(19) United States
(12) Patent Application Publication
(10) Pub. No.: US 2025/0167792 A1
(43) Pub. Date: May 22, 2025

(54) DITHERING BASED DIGITAL TO TIME CONVERTER LINEARIZATION TECHNIQUE

(71) Applicant: University of Southern California, Los Angeles, CA (US)

(72) Inventors: Shuo-Wei Chen, Los Angeles, CA (US); Qiaochu Zhang, Los Angeles, CA (US)

(21) Appl. No.: 18/887,955

(22) Filed: Sep. 17, 2024

Related U.S. Application Data
(60) Provisional application No. 63/600,557, filed on Nov. 17, 2023.

(51) Int. Cl. H03M 1/06; H03L 7/08

(52) U.S. Cl. CPC H03M 1/0604; H03L 7/08

(57) ABSTRACT

An electrical circuit for clock generation includes a digital-to-time converter error scrambler configured to randomize error in a digital-to-time converter (DTC) and configured to suppress spurs of the electrical circuit, a background error compensator configured to mitigate a timing mismatch between an injection of a reference signal into the DTC at a first point and an injection of the reference signal into the DTC as a second point, and a background delay equalizer configured to calibrate errors of the electrical circuit.

### CROSS-REFERENCE TO RELATED PATENT APPLICATIONS

This application claims the benefit of and priority to U.S. Provisional Patent Application No. 63/600,557 filed on Nov. 17, 2023, the entirety of which is incorporated by reference herein.

### STATEMENT REGARDING FEDERALLY SPONSORED RESEARCH OR DEVELOPMENT

This invention was made with government support under Grant Number FA8650-18-2-7853, awarded by the Defense Advanced Research Projects Agency (DARPA). The government has certain rights in the invention.

### SUMMARY

One embodiment relates to an electrical circuit for clock generation. The electrical circuit includes a digital-to-time converter error scrambler configured to randomize error in a digital-to-time converter (DTC) and configured to suppress spurs of the electrical circuit, a background error compensator configured to mitigate a timing mismatch between an injection of a reference signal into an oscillator at a first point and an injection of the reference signal into the oscillator as a second point, and a background delay equalizer configured to calibrate errors of the electrical circuit.

In some embodiments, randomization from the digital-to-time converter error scrambler and calibration from the background delay equalizer occur simultaneously. In some embodiments, randomization from the digital-to-time converter error scrambler and calibration from the background delay equalizer occur independently. In some embodiments, the errors calibrated by the background delay equalizer are any one of a digital-to-time converter offset, a digital-to-time converter gain, or an integral-nonlinearity (INL) error. In some embodiments, the errors exist at least one point of a phase-locked loop. In some embodiments, a timing mismatch is associated with the digital-to-time converter error scrambler. In some embodiments, the electrical circuit is further configured to include one or more of a pulse window generator, an injection path, a digital-controlled oscillator, an injection mixer, an injection digital-to-time converter, or a calibration digital-to-time converter. In some embodiments, outputs of the background error compensator and the background delay equalizer are combined digitally before adjusting a delay of a calibration digital-to-time converter. In some embodiments, the pulse window generator controls the timing of a reference injection and an injection polarity.

Another embodiment relates to an electrical circuit for clock generation. The electrical circuit includes an oscillator, a digital-to-time converter (DTC) error scrambler configured to randomize error in a DTC and configured to suppress spurs of the electrical circuit, wherein the DTC error scrambler comprises control code to control a delay of one or more injection DTCs, a background error compensator configured to mitigate a timing mismatch between an injection of a reference signal into the oscillator at a first point and an injection of the reference signal into the oscillator at a second point, and a background delay equalizer configured to calibrate errors of the electrical circuit, wherein the errors comprise a plurality of error components.

In some embodiments, the background delay equalizer includes a digital domain corrector configured to tune the oscillator to align with a phase of at least one of the injection DTCs to control a first error component of the plurality of error components, a current source configured to control a second error component of the plurality of error components, and a calibration digital-to-time converter (DTC) configured to control a third error component of the plurality of error components. In some embodiments, the first error component is a digital-to-time converter offset error, the second error component is a digital-to-time converter gain error, and the third error component is a digital-to-time converter INL error. In some embodiments, the calibration DTC controls the third error component by reducing a delay range relative to a delay range of an injection DTC.

In some embodiments, the background error compensator mitigates the timing mismatch between the injection of the reference signal into the oscillator at the first point and the injection of the reference signal into the oscillator at the second point by: extracting, by the background error compensator, using a filter, the timing mismatch between the injection of the reference signal at the first point and the injection of the reference signal at the second point, and tuning control code of the calibration DTC to calibrate a time delay of one or both of the injection of the reference signal at the first point and the injection of the reference signal at the second point. In some embodiments, the electrical circuit further includes a reference signal configured to periodically refresh a signal of the oscillator to suppress noise in the oscillator. In some embodiments, the reference signal is a low noise signal. In some embodiments, a total delay of the one or more injection DTCs is determined based on a product of a gain of the injection DTC and the control code of the injection DTC. In some embodiments, the background delay equalizer comprises a least mean square filter.

Still another embodiment relates to a method. The method includes controlling, using a digital-to-time converter (DTC) error scrambler, a delay of one or more injection DTCs of an electrical circuit, mitigating, using a background error compensator, a timing mismatch between an injection of a reference signal into an oscillator at a first point and an injection of the reference signal into the oscillator as a second point, wherein mitigating the timing mismatch comprises injecting the reference signal into one of a rising edge or a falling edge of the signal of the oscillator, and calibrating, using a delay equalizer, error of the electrical circuit, the error comprising a plurality of error components.

In some embodiments, calibrating the plurality of error components includes tuning a signal of the oscillator to align with a phase of at least one of the one or more injection DTCs to control a first error component of the plurality of error components, controlling a current source to correct a gain of the injection DTC, and tuning a delay range relative to a delay range of an injection DTC via a calibration DTC. In some embodiments, mitigating the timing mismatch between the injection of the reference signal into the oscillator at the first point and the injection of the reference signal into the oscillator at the second point includes extracting, by the background error compensator, using a filter, the timing mismatch between the injection of the reference signal at the first point and the injection of the reference signal at the second point, and tuning control code of the calibration DTC to calibrate a time delay of one or both of the injection of the reference signal at the first point and the injection of the reference signal at the second point.

### BRIEF DESCRIPTION OF THE DRAWINGS

FIG. 1 is an architecture of a conventional phase-locked loop, according to an exemplary embodiment.

FIG. 2 is a circuit diagram of a phase locked loop, according to an exemplary embodiment.

FIG. 3 is a circuit diagram of a DTC error scrambler and a background error compensator, according to an exemplary embodiment.

FIG. 4 is a block diagram of an injection error scrambling technique, according to an exemplary embodiment.

FIG. 5A depicts an injection error scrambling algorithm, according to an exemplary embodiment.

FIG. 5B depicts the injection error scrambling algorithm of FIG. 5A, according to an exemplary embodiment.

FIG. 6 depicts an effect of the DTC error scrambler on waveforms, according to an exemplary embodiment.

FIG. 7A depicts waveforms without an effect of the DTC error scrambler, according to an exemplary embodiment.

FIG. 7B depicts waveforms with an effect of the DTC error scrambler, according to an exemplary embodiment.

FIG. 7C depicts waveforms without an effect of the DTC error scrambler, according to an exemplary embodiment.

FIG. 7D depicts waveforms with an effect of the DTC error scrambler, according to an exemplary embodiment.

FIG. 8A is a timing diagram of injection polarity error, according to an exemplary embodiment.

FIG. 8B is a depiction of example physical causes of injection polarity error, according to an exemplary embodiment.

FIG. 9A is a depiction of a time domain waveform of injection polarity control code, according to an exemplary embodiment.

FIG. 9B is a depiction of a power spectral density of the injection polarity control code of FIG. 9A, according to an exemplary embodiment.

FIG. 10 is a block diagram of a background error compensator, according to an exemplary embodiment.

FIG. 11 is a block diagram of digital-to-time converter transfer functions with digital-to-time converter errors, according to an exemplary embodiment.

FIG. 12 is a circuit diagram of example physical causes of various digital-to-time converter errors, according to an exemplary embodiment.

FIG. 13 is an output spectrum of a phase-locked loop with digital-to-time converter errors, according to an exemplary embodiment.

FIG. 14 is a block diagram of a multipoint correction of a background delay equalizer, according to an exemplary embodiment.

FIG. 15 is a circuit diagram of an implementation of a background delay equalizer, according to an exemplary embodiment.

FIG. 16 is a block diagram showing an effect of injection error scrambling and a background delay equalizer in both the time and the frequency domains, according to an exemplary embodiment.

FIG. 17 is a circuit diagram of a digitally controlled oscillator and an embedded time-to-digital converter, according to an exemplary embodiment.

FIG. 18 is a block diagram of an injection path and injection control circuits, according to an exemplary embodiment.

FIG. 19A is a block diagram of a pulse window generator, according to an exemplary embodiment.

FIG. 19B is a timing diagram of the pulse window generator of FIG. 19A, according to an exemplary embodiment.

FIG. 20 is a circuit diagram of an injection mixer, according to an exemplary embodiment.

FIG. 21 is a circuit diagram of a multiplexer of the injection mixer of FIG. 21, according to an exemplary embodiment.

FIG. 22 is a circuit diagram of an injection digital-to-time converter, according to an exemplary embodiment.

FIG. 23 is a circuit diagram of a calibration digital-to-time converter, according to an exemplary embodiment.

FIG. 24 is a circuit diagram of an injection path with ring oscillator and a digital-to-time converter reset code, according to an exemplary embodiment.

FIG. 25 is a circuit diagram of an implementation of a DTC error scrambler, according to an exemplary embodiment.

FIG. 26 is a block diagram of a method of clock generation, according to an exemplary embodiment.

### DETAILED DESCRIPTION

Referring generally to the FIGURES, a phase locked loop (PLL) is shown. In some embodiments, the PLL may be a multiplying delay-locked loop (MDLL). Phase-locked loops may be used for clock generation. Ring-oscillator (RO)-based injection-locked phase-locked loops (IL-PLLs) and MDLLs are specific types of PLLs. A digital-to-time converter (DTC) error scrambling technique that allows a higher degree of randomization and suppresses spurs, a background error compensation technique that mitigates the timing mismatch associated with the DTC error scrambling, and a background delay equalizer that corrects DTC offset, DTC gain, and integral-nonlinearity (INL) errors at multiple points of an MDLL, may be used to reduce spurs and noise in the PLL. The circuit may come with a relaxed analog implementation requirement. The systems and methods described in the figures use a multiplying delay-locked loop as an exemplary embodiment. The invention is not limited to use in a multiplying delay-locked loop and may be utilized for any phase-locked loop.

This technical solution is directed to PLLs that utilize techniques to avoid the problem of the generation of reference or fractional spurious tones that is seen in PLLs used for clock generation. This application is directed to a DTC error scrambling technique that allows a higher degree of randomization and suppresses spurs, a background error compensation technique that mitigates a timing mismatch associated with DTC error scrambling, and a background delay equalizer that corrects DTC offset, DTC gain, and INL errors at multiple points of a PLL, with a relaxed analog implementation requirement.

These and other aspects and implementations are discussed in detail below. The foregoing information and the following detailed description include illustrative examples of various aspects and implementations, as well as provide an overview or framework for understanding the nature and character of the claimed aspects and implementations. The drawings provide illustration and a further understanding of the various aspects and implementations and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of ‘a’, ‘an’, and ‘the’ include plural referents unless the context clearly dictates otherwise.

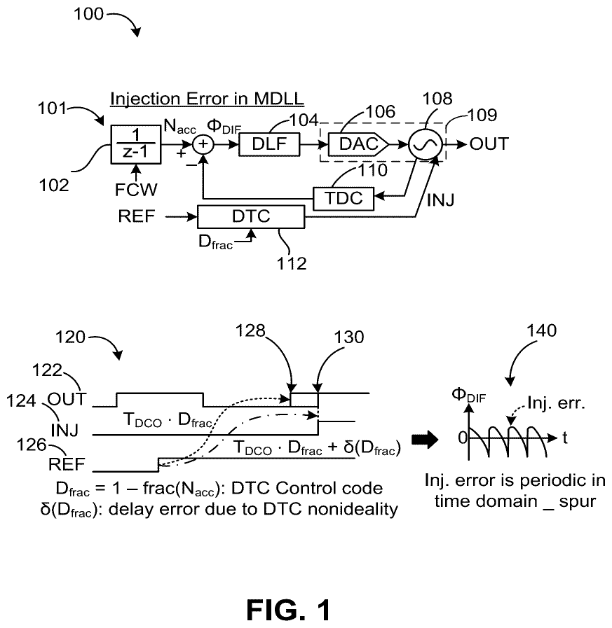

Referring to FIG. 1, an architecture 100 for a conventional phase-locked loop (PLL) is shown, according to an example embodiment. Specifically, a fractional-N MDLL is shown. In various embodiments, another type of PLL may be used. For example, methods described herein may be applied to the DTCs in fractional-N subsampling PLLs. The architecture 100 includes an exemplary electrical circuit 101 for the phase-locked loop. Conventional PLLs (e.g., the PLL indicated by the circuit 101) may include large amounts of noise. The circuit 101 includes a frequency control word (FCW) 102, a digital loop filter (DLF) 104, a digital-to-analog converter (DAC) 106, an oscillator 108, a time-to-digital converter (TDC) 110, and a digital-to-time (DTC) converter 112. The FCW 102 may be a number or other value defined as a ratio between a frequency of an output signal, represented in FIG. 1 as OUT, and a frequency of a reference clock signal, represented in FIG. 1 as REF. In various embodiments, the value of the FCW 102 may accumulate. The FCW 102 may be accumulated using a digital integrator, shown in FIG. 1 as the function 1/(z−1). The accumulated value of the FCW 102 (e.g., the output of the digital integrator 1/(z−1) may represent or indicate an incremental phase change per clock cycle of an output waveform of the circuit 101.

The DLF 104 may be configured to process a phase detector and/or an error signal generated by the PLL and generate a control signal. The control signal may be used to adjust the circuit 101 (e.g., operation of the circuit 101) such that a desired performance of the circuit 101 is maintained. For example, a phase detector of the DLF 104 may compare a phase of a reference signal with a phase of a signal from the oscillator 108. Based on the difference between the phases, the phase detector of the DLF 104 may generate an error signal. The DLF 104 may further process the error signal to smooth and/or filter the signal. The filtered output signal is used as a control signal to control behavior of the MDLL. For example, the control signal may adjust a frequency of the oscillator 108.

The DAC 106 may be configured to convert a digital signal to an analog signal. For example, the DAC 106 may receive a digital input (e.g., a binary number representing an amplitude of a signal) and convert the digital input to a corresponding analog signal. The analog signal may be, for example, an analog voltage or current corresponding to the signal amplitude represented by the binary number.

The oscillator 108 may generate a continuous, periodic (e.g., sinusoidal) signal. The signal may be the output of the circuit 101.

The TDC 110 may measure or otherwise determine a time interval between two signals. For example, the TDC 110 may determine a time interval (e.g., a delay) between a rising edge of a reference signal and a rising edge of a signal from the oscillator 108. The TDC 108 may convert the time interval into a digital value (e.g., a binary number).

The DTC 112 may be configured to convert a digital value into a time value (e.g., a time interval). Specifically, in a locked loop circuit (e.g., an IL-PLL), the DTC 112 may be configured to delay a reference-injection signal such that the signal aligns with a phase of the signal from the oscillator 108. The DTC 112 may delay the reference-injection signal with a specific phase shift (e.g., a fractional-N phase shift).

The PLL 101 may utilize the DTC 112 to delay a reference clock, shown in FIG. 1 as REF. A phase of the reference clock may be aligned with an immediate rising edge of a digital-controlled oscillator (DCO) 109 (e.g., the DAC 106 and the oscillator 108). The REF signal may be a clean signal. An edge of the DCO 109 may be noisier than an edge of the REF signal. Replacing the DCO 109 with the REF signal may achieve in-band phase noise suppression.

In various embodiments, a real injection point of the reference signal by the DTC 112 may deviate from an ideal injection point of the reference signal. For example, the real injection point of the reference signal may cause the reference signal to be out of phase with the output signal from the oscillator 108. The deviation may be caused by non-idealities associated with the DTC 112. Further, the deviation may cause periodic error in the reference signal. In various embodiments, the periodic error caused by a deviation between an ideal injection point of the reference signal REF into the DCO 109 and a real injection point of the reference signal REF into the DCO 109 may appear as a “spur” in the frequency domain. For example, in the time domain, the deviation of the real injection point from the ideal injection point may be referred to as error, and in the frequency domain, the error may appear as or be referred to as a spur or spurious tone.

FIG. 1 further includes a graphical representation 120 of a deviation between the output signal and the injection signal. As shown in the output signal graph 122, point 128 indicates a rising edge of the output signal. Injection signal graph 124 indicates, at point 130, when the reference signal (shown by reference signal graph 126) is injected. As shown in the output signal graph 122, an ideal injection point of the reference signal is at point 128 (e.g., so the output signal is synchronized with the rising edge of the reference signal). Due to a delay in the injection of the reference signal, there exists a delay or timing mismatch between the ideal injection position and the real injection position (e.g., an injection error). As shown by time versus phase plot 140, this injection error may be periodic in the time domain (e.g., as shown in the plot 140). The injection error may appear as spurs (also referred to as “spurious tones”) in a frequency domain.

The delay of the DTC 112 may be shown as T_{DCO}×D_{frac}[n], where D_{frac}[n]=1−frac (ϕ_{acc}[n]/2π). T_{DCO} is a period of the DCO 109. ϕ_{acc}[n] represents an accumulated phase from the FCW 102, which may indicate ideal or near-ideal positions of edges of the DCO 109. The value of D_{frac} may be within [0, 1). D_{frac}[n] may be determined by a fractional part of an accumulated result N_{acc} of the FCW 102. D_{frac}[n] may be periodic. The periodic D_{frac}[n] pattern during fractional-N operation may cause or create a periodic phase error at an output of the DTC 112 when coupled with a DTC gain error, an offset error and/or an INL error. The error may be injected into the DCO and may cause fractional spurs.

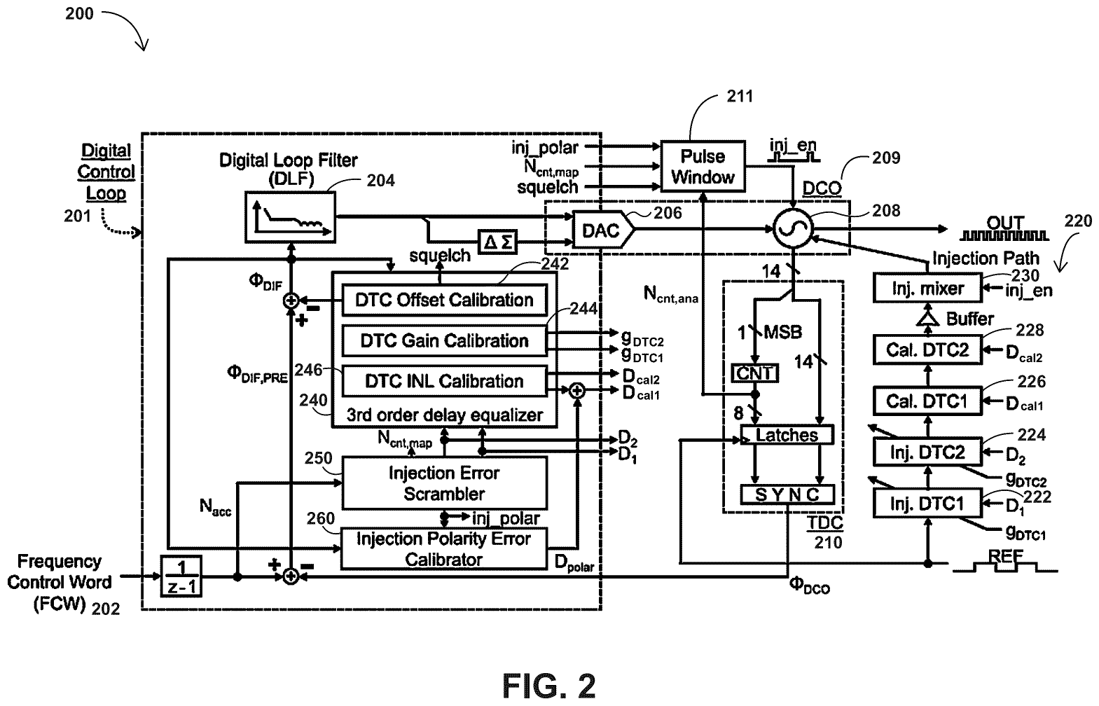

Referring now to FIG. 2, a circuit diagram of a phase locked loop 200 is shown, according to an exemplary embodiment. Specifically, the PLL 200 includes a plurality of elements to reduce a phase noise level that may be present in a conventional PLL (e.g., the PLL 101 shown in FIG. 1). The PLL 200 may include similar elements as the PLL 101. For example, the PLL 200 may include a FCW 202, a DLF 204, a DAC 206, an oscillator 208, and a TDC 210. In some embodiments, the DAC 206 and the oscillator 208 may comprise a digitally controlled oscillator (DCO) 209. Each of the FCW 202, the DLF 204, the DAC 206, the oscillator 208, and the TDC 210 may be similar to the FCW 102, the DLF 104, the DAC 106, the oscillator 108, and the TDC 110 described with respect to FIG. 1. The PLL 200 may include additional elements. For example, the PLL 200 may include a pulse window 211, an injection path 220, a DTC error scrambler 250, a background error compensator 260, and a background delay equalizer 240, each of which will be described in greater detail herein.

The PLL 200 may be or include a type-II PLL. During normal operation, the DTC error scrambler 250 and the background delay equalizer 240 may be enabled simultaneously. In some embodiments, the DTC error scrambler 250 and the background delay equalizer 240 may be enabled individually (e.g., successively, etc.). The outputs of the background error compensator 260, Dₚₒₗₐᵣ, and the background delay equalizer 240 may be combined digitally before adjusting a delay of the calibration DTCs (e.g., calibrations 242, 244, and 246) to minimize analog complexity.

The injection path 220 be configured to reduce an amount of noise present in the PLL 200. The injection path 220 may include a reference signal 221, a first injection DTC 222, a second injection DTC 224, a first calibration DTC 226, a second calibration DTC 228, and an injection mixer 230. While the injection path 220 is configured to reduce noise in the PLL 200, the injection path 220 may include or cause non-idealities in the PLL 200. For example, there may be a voltage change, a temperature change, a fabrication defect, etc. in the PLL 200, which may cause the PLL 200 or the injection path 220 to behave in a non-ideal manner. As such, one or more of the DTC error scrambler 250, the background error compensator 260, and the delay equalizer 240 may be utilized or implemented in the PLL 200 to correct or calibrate the non-ideal behavior (e.g., error) of the injection path 220. The error caused by the injection path 220 may be periodic. Periodic error may periodically disturb the output signal of the PLL 200 (e.g., the output signal of the oscillator 208), causing spurs in a spectrum or frequency plot. As such, it may be beneficial to suppress error caused by the injection path 220, thus suppressing spurs.

The effects of the non-ideality of the injection path 220 may be mitigated by calibration and/or randomization. Calibration may include directly extracting error and correcting one or more hardware elements in the injection path 220 (e.g., one or more components of the injection path 220). Randomization may include randomizing control code from the DTC error scrambler 250 using two injection DTCs (e.g., the first and second injection DTCs 222 and 224). Randomizing the control code may cause the error to be random rather than periodic. Thus, the error caused by the injection path 220 may appear as noise rather than spurs in a spectrum plot of the output signal from the oscillator 208.

In various embodiments, calibration may be performed prior to randomization. In various other embodiments, calibration may be performed concurrent with or subsequent to randomization. First performing calibration may reduce or lower an error level. Calibration may be performed using a calibration algorithm. Further, calibration algorithms may have associated accuracy limits (e.g., calibration may reduce error to within a certain accuracy range or level). Randomization may then be performed to further reduce the error or spur level, in order to enable the final output signal to perform with improved accuracy compared to the accuracy provided by calibration alone. Randomization may be performed using a randomization algorithm.

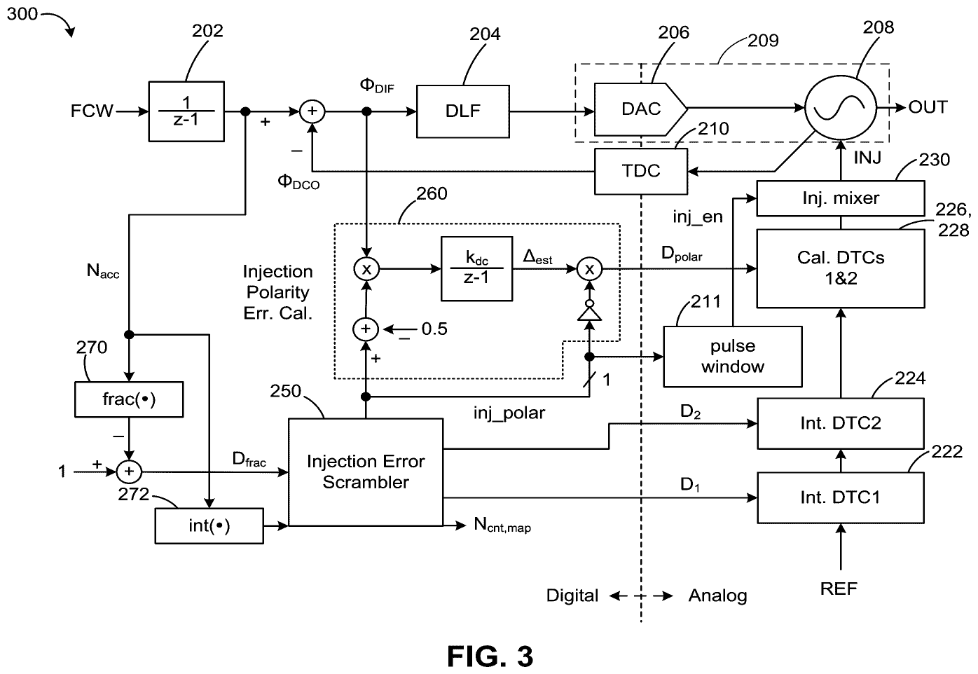

The reference signal 221 may be a periodic (e.g., sinusoidal) signal. The reference signal may also be referred to as a reference clock. Further, the reference signal 221 may be a low-noise signal that is periodically injected into the PLL 200. The reference signal may refresh the signal from the oscillator 208 such that noise is suppressed. Each of the first injection DTC 222, the second injection DTC 224, the first calibration DTC 226, the second calibration DTC 228, and the injection mixer 230 will be described in greater detail with respect to FIGS. 3-10. Further, FIGS. 3-26 may make reference to various components of the PLL 200 (e.g., a DCO, an oscillator, injection DTCs, calibration DTCs, etc.). It should be understood that the components described with respect to these figures may be the same as or similar to the components described with respect to FIG. 2.

The first and second injection DTCs 222 and 224 may be digital to time converters configured to convert the injection signals from digital signals to time periods. As shown, a totally delay for each of the first and second injection DTCs 222 and 224 may be determined by multiplying the control code used as a digital input to each of the injection DTCs 222 and 224 with a gain of each of the input control codes. For example, D₁ may be the control code used as an input into the first injection DTC 222. D₁ may be multiplied by the gain of the first injection DTC 222, g_{DTC1}, to determine the total delay of the first injection DTC 222.

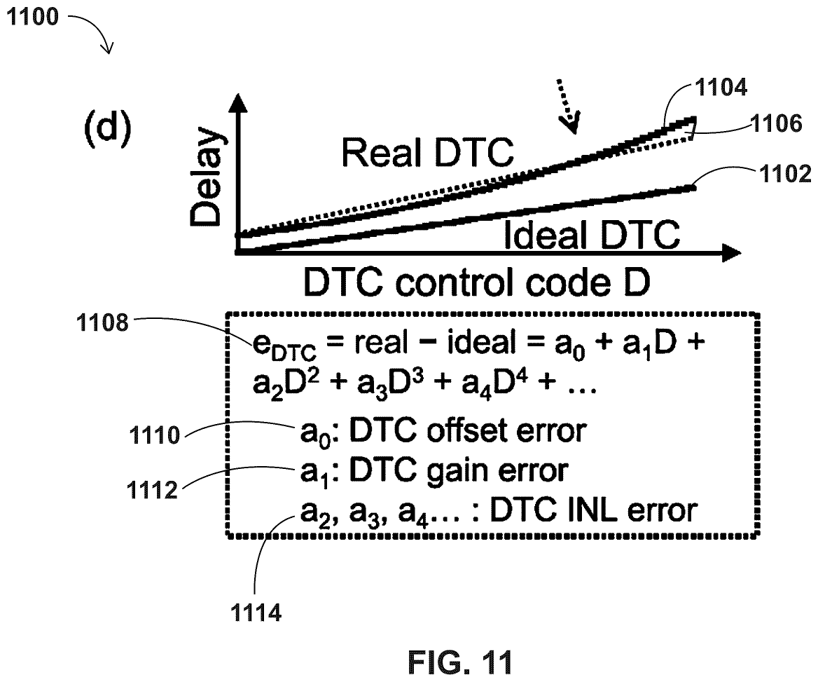

The first and second calibration DTCs 226 and 228 may be configured to calibrate errors caused by the DTC. The first and second calibration DTCs 226 and 228 will be described in greater detail with respect to FIGS. 11-16.

The injection mixer 230 may be configured to regulate the timing and polarity of the injection of the reference signal 221.

The DTC error scrambler 250 may be configured to randomize error in a DTC and may suppress spurs generated in the PLL 200. The DTC error scrambler may also be referred to herein as a DTC error scrambler 250. The DTC error scrambler 250 may be a control circuit to control the first and second injection DTCs 222 and 224. As described above, the DTC error scrambler 250 may include control code and/or a randomization algorithm to randomize injection of the reference signal 221. The DTC error scrambler 250 will be described in greater detail with respect to FIGS. 3-10.

The background error compensator 260 may be configured to mitigate a timing mismatch between an injection of the reference signal 221 into the DCO 209 at a first point (e.g., one of a rising edge or a falling edge of the DCO) and an injection of the reference signal into the DCO 209 at a second point (e.g., the other of the rising edge or the falling edge of the DCO). For example, the timing of injection of the reference signal 221 may cause a timing mismatch between a rising edge and a falling edge of the DCO. Randomization of the injection of the reference signal 221 may cause the reference signal 221 to be injected at both a rising edge and a falling edge of the signal of the oscillator 208. Due to the injection at both edges, the timing mismatch may occur between the rising edge and the falling edge injections. Thus, the background error compensator 260 may mitigate or suppress a negative effect of the timing mismatch. The background error compensator may be referred to herein as an injection polarity error calibrator 260. The background error compensator 260 will be described in greater detail with respect to FIGS. 3-10.

The background delay equalizer 240 may be configured to calibrate errors of the PLL 200. The background delay equalizer 240 may be referred to herein as a delay equalizer 240. The background delay equalizer 240 may include a DTC offset calibration 242, a DTC gain calibration 244, and/or a DTC injection non-linearity calibration 246. The background delay equalizer 240 will be described in greater detail with respect to FIGS. 11-16.

The pulse window 211 may control the timing of the reference injection and the injection polarity. The TDC 210 may include a plurality of elements. For example, the TDC 210 may include a plurality of latches to record the most significant bit (MSB) generating from a counter (CNT), and combine with other bits generating from fine TDC. The TDC 210 may be configured to convert an analog signal to a digital signal. Each of the pulse window 211 and the TDC 210 are described in greater detail herein.

Referring generally to FIGS. 3-10, a DTC error scrambling scheme is shown, according to an example embodiment. More specifically, an injection error scrambling scheme is shown. In various embodiments, a different type of DTC error scrambling scheme may be used. An injection error scrambling scheme may be used to create a DTC error randomization scheme that is compatible with periodic reference injection operations with two DTCs.

Referring now to FIG. 3, a circuit diagram of a PLL 300 including a DTC error scrambler 250 and a background error compensator 260 is shown, according to an exemplary embodiment. The PLL 300 may be the same as or similar to the PLL 200 described with respect to FIG. 2, without the delay equalizer 240 shown.

As stated previously, the DTC error scrambler 250 may receive or include control code, shown as D_{frac}. D_{frac} may also be referred to herein as D or D[n]. The DTC error scrambler 250 may divide the control code D_{frac} into one or more paths (e.g., two paths), shown as D₁ and D₂. As used throughout, D₁ and D₂ may be referred to D₁[n] and D₂[n]. In various embodiments, the control code D_{frac} may be divided into three paths, four paths, etc. In some embodiments the control code may not be divided into multiple paths. The PLL 300 may include a number of injection DTCs corresponding to the number of paths the control code D_{frac} is divided into. Each of D₁ and D₂ may be used as digital signal inputs into the first and second injection DTCs 222 and 224, respectively. Splitting the control code D_{frac} into multiple paths or groups may allow each path to be independently controlled. This may allow for one or more degrees of freedom to tune or adjust each of the injection DTCs to convert the control code entering the injection DTC into noise. For example, the use of two or more injection DTCs may allow different parameters to applied to each injection DTC to reduce the periodicity of error as much as possible.

In various embodiments, the injection error of the PLL is code-dependent. The DTC error scrambler 250 may break the periodicity of injection error. For example, the periodicity of the injection error may be broken by randomly distributing an injection delay to two injection DTCs (e.g., the first injection DTC 222 and the second injection DTC 224) and scrambling the injection position between the rising and the falling edges of the DCO 209. The background error compensator 260 may calibrate a polarity of the injection (e.g., whether the reference signal 221 is injected into a rising edge or a falling edge of the oscillator signal) and mitigate a mismatch between the rising edge injection and the falling edge injection. Additional features of FIG. 3 will be further described herein.

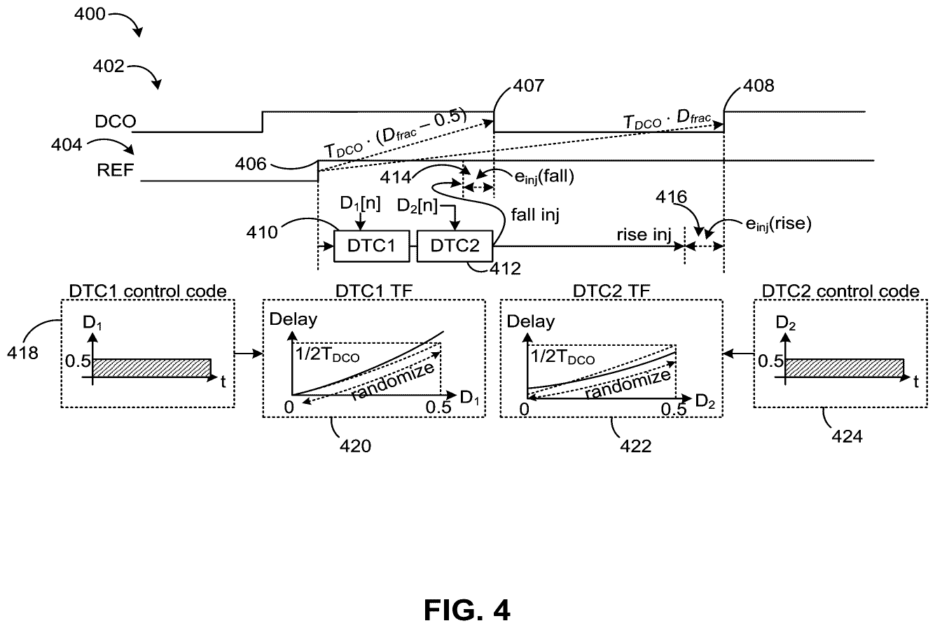

Referring now to FIG. 4, a block diagram 400 of an injection error scrambling technique is shown, according to an exemplary embodiment. For example, the block diagram 400 shows the injection error scrambling scheme of FIG. 3. As stated above, an injection DTC may be partitioned into multiple individually controlled DTCs. For example, one injection DTC may be partitioned into DTC1 410 and DTC2 412. DTC1 410 and DTC2 412 may be the same as or similar to the first and second injection DTCS 222 and 224, respectively. Both of the DTC1 410 and the DTC2 412 may have a complete tuning range of 0.5 T_{DCO} (i.e., the DTC control codes (D₁ and D₂) may range within [0, 0.5]). Injection error scrambling may (a) randomly distribute a required delay to the DTC1 410 and the DTC2 412 and/or (b) toggle an injection polarity between a rising edge (e.g., rising edge 408) and a falling edge (e.g., falling edge 407) of the DCO 402. The DCO 402 may be the same as or similar to the DCO 209. Injection error scrambling may achieve a high degree of freedom for randomization, and therefore, code-dependent DTC errors are largely scrambled. This may suppress the spurious tones.

As shown in FIG. 4, it may be desirable to delay the rising edge 406 of the reference clock 404. The rising edge 406 may be delayed to the falling edge 407 or the rising edge 408 of the DCO 402, in order to achieve synchronization. The delay of the reference clock 404 may be distributed between the DTC1 410 and the DTC2 412.

Graphs 418 and 424 illustrate time versus control code plots for the DTC1 410 and the DTC2 412, respectively. Graphs 420 and 422 illustrate transfer function plots for the DTC1 410 and the DTC2 412, respectively. Under ideal conditions, the transfer function or control code to delay relationship may be linear. Under non-ideal conditions (e.g., such as those caused by the injection path 220), the transfer function may be non-linear as a result of higher order terms used to represent the injection error. As shown in graphs 420 and 422, an area between the idea linear line and the non-ideal non-linear line may represent the injection error of the DTC1 410 and the DTC2 412, respectively. As shown in plots 418 and 424, the control code may appear as or have a signal similar to a noise signal. As shown in transfer function graphs 420 and 422, when the control code is randomized, the error may also be randomized, thus eliminating periodic error. As such, the injection error appearing in each of the DTC1 410 and the DTC2 412 may appear as noise or noise-like.

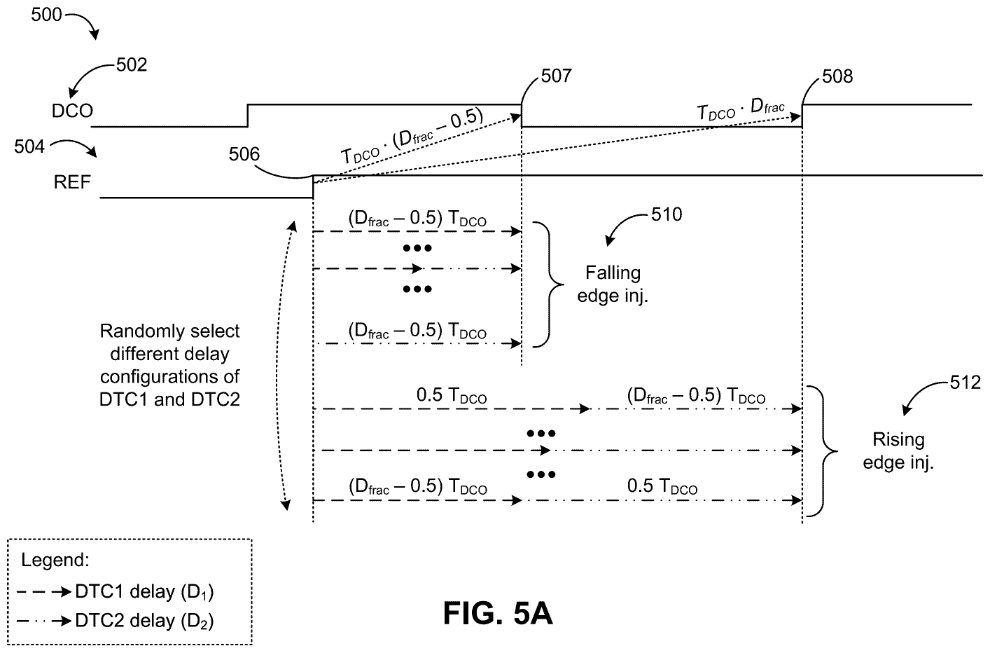

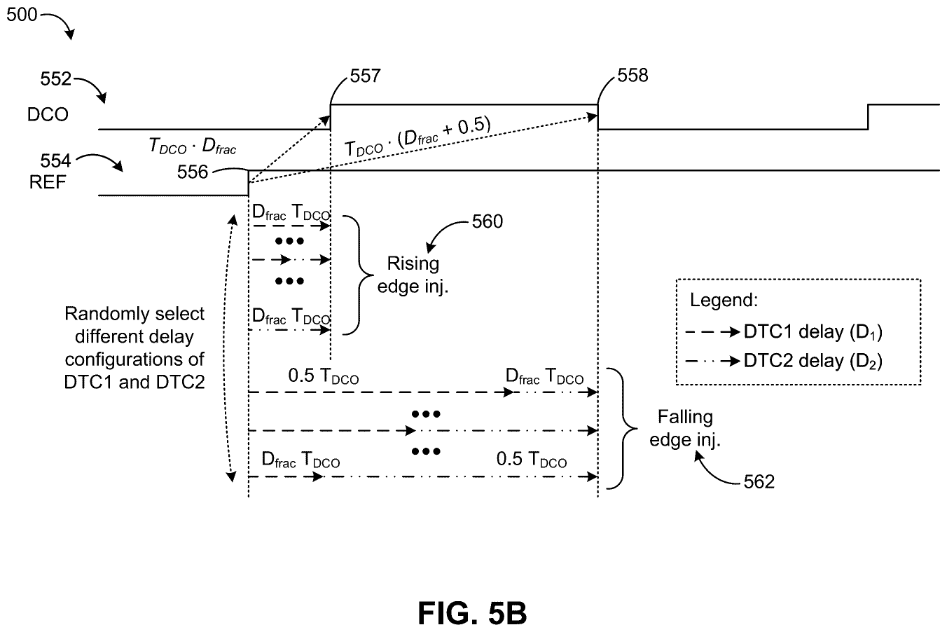

Referring now to FIGS. 5A and 5B, injection error scrambling algorithms are shown, according to exemplary embodiments. A D₁ value may be generated. For example, a D₁ value between 0 and 0.5 may be generated. In some embodiments, the D₁ value may be generated using a pseudo-noise (PN) generator. The repetitive period of PN may be larger than a maximum value of D_{frac}. For example, the D_{frac} may have a maximum repetitive period of 27, and the repetitive period of the PN generator may be 2¹⁶. A corresponding D₂ code may also be generated by a PN generator. The value of the D₂ code may be randomly distributed (e.g., between 0 and 0.5). The total delay of DTC1 410 and DTC 412 may be defined as T_{DCO}×(D₁+D₂). The total delay may randomly achieve values calculated as T_{DCO}×D_{frac} or T_{DCO}×(D_{frac}+0.5), depending on whether the rising edge 506 of the reference clock 504 is located between a rising edge and a falling edge of the DCO 502 (as in FIG. 5A) or whether the rising edge 556 is located between a falling edge and a rising edge of the DCO 552 (as in FIG. 5B). The total delay may be randomly distributed between T_{DCO}×D_{frac} and T_{DCO}×(D_{frac}+0.5). For example, when the reference clock is injected at a rising edge 508 or 557 of the DCO, the total delay may be T_{DCO}×D_{frac}. When the reference clock is injected at a falling edge 507, the total delay may be T_{DCO}×(D_{frac}−0.5). When the reference clock is injected at a falling edge 558, the total delay may be T_{DCO}×(D_{frac}+0.5). Randomized injection locking at the one or both of the DCO 502 rising edge 508 and/or falling edge 507 may occur due to the total delay. This may be referred to as injection polarity. Code-dependent DTC errors (e.g., err1 and err2 resulting from D₁, D₂, respectively, and injection polarity) may be scrambled (e.g., randomized). The scrambled errors may result in a noise-like injection error without causing spurious tones in the PLL. The injection error scrambling algorithm will be explained in greater detail herein.

Referring still to FIGS. 5A and 5B, the phase configuration may be divided into two parts: when the reference clock is closer to the next DCO falling edge (D_{frac}≥0.5), as shown in FIG. 5A, and when the rising edge of the reference clock is closer to the next DCO rising edge (D_{frac}<0.5), as shown in FIG. 5B. FIG. 5A illustrates an algorithm 500 for determining the delay provided by each of the first and second injection DTCs 410 and 412. As shown, a rising edge 506 of the reference clock 504 may occur before a rising edge 508 or a falling edge 507 of the DCO 502. As such, the DTC1 410 and/or the DTC2 412 may be used to delay the reference clock 504 such that the rising edge 506 aligns with the falling edge 507 or the rising edge 508. Delays 510 may be used, calculated, determined, etc. when the reference clock 504 is injected at the falling edge 507. Delays 512 may be used, calculated, determined, etc. when the reference clock 504 is injected at the rising edge 508. As described above, the total delay may include varying proportions of the delays provided by the DTC1 410 and the DTC2 412.

Since the DTC has a range of delay tuning, different delay assignments may be chosen for the DTC1 410 and the DTC2 412 when injecting at the rising edge 508. For example, in one embodiment, a maximum delay of the DTC1 410 may be set to 0.5 T_{DCO}. The DTC2 412 may provide the remaining delay. Alternatively, the delay of DTC1 may be gradually decreased until the delay of DTC2 reaches a maximum value of 0.5 T_{DCO}. The delay of the DTCs 410 and 412 may be tuned between 0.5 T_{DCO} and (D_{frac}−0.5) T_{DCO}, respectively. Similarly, for example, if injecting at a next DCO falling edge 407, the delay of the DTCs 410 and 412 may vary between zero and (D_{frac}−0.5) T_{DCO}. Injecting the reference clock 504 using various combinations of the falling edge delays 510 and the rising edge delays 512 may produce different configurations for injecting at the rising and falling edges of DCO 502. The DTC error scrambler 250 may randomly select these configurations with uniform probability and inject the reference clock to an associated edge of the DCO 502.

Referring now to FIG. 5B, an algorithm 550 for determining the delay provided by each of the first and second injection DTCs 410 and 412 is shown, according to an example embodiment. The injection error scrambling algorithm described above with respect to FIG. 5A may be applicable to a situation in which D_{frac}<0.5, as shown in FIG. 5B. As a result, the delays of DTC1 and DTC2 may randomly toggle between zero and 0.5 T_{DCO} (i.e., exercising the whole DTC transfer function with a uniform probability distribution). Consequently, the code-dependent DTC errors may be randomized throughout the transfer function, resulting in a noise-like injection error without generating spurious tones in the PLL.

As shown, a rising edge 556 of the reference clock 554 may occur before a rising edge 557 or a falling edge 558 of the DCO 552. As such, the DTC1 410 and/or the DTC2 412 may be used to delay the reference clock 554 such that the rising edge 556 aligns with the falling edge 558 or the rising edge 557. Delays 560 may be used, calculated, determined, etc. when the reference clock 554 is injected at the rising edge 557. Delays 562 may be used, calculated, determined, etc. when the reference clock 554 is injected at the falling edge 558. As described above, the total delay may include varying proportions of the delays provided by the DTC1 410 and the DTC2 412.

Since the DTC has a range of delay tuning, different delay assignments may be chosen for the DTC1 410 and the DTC2 412 when injecting at the rising edge 557 or the falling edge 558. For example, in one embodiment, a maximum delay of the DTC1 410 may be set to 0.5 T_{DCO}. The DTC2 412 may provide the remaining delay. Alternatively, the delay of DTC1 may be gradually decreased until the delay of DTC2 reaches a maximum value of 0.5 T_{DCO}. The delay of the DTCs 410 and 412 may be tuned between 0.5 T_{DCO} and (D_{frac}+0.5) T_{DCO}, respectively. Similarly, for example, if injecting at a next DCO falling edge 558, the delay of the DTCs 410 and 412 may vary between zero and (D_{frac}+0.5) T_{DCO}. Injecting the reference clock 554 using various combinations of the falling edge delays 562 and the rising edge delays 560 may produce different configurations for injecting at the rising and falling edges of DCO 552. The DTC error scrambler 250 may randomly select these configurations with uniform probability and inject the reference clock to an associated edge of the DCO 552.

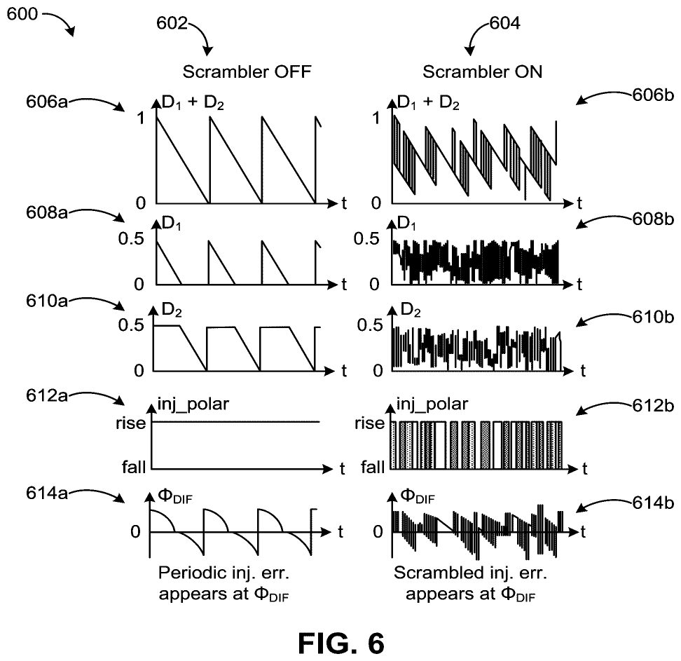

Referring now to FIG. 6, a chart 600 illustrating the effect of the DTC error scrambler 250 on waveforms of the PLL 200 is shown, according to an example embodiment. For example, column 602 includes a plurality of time-domain waveforms 606a, 608a, 610a, 612a, and 614a for different control codes when the DTC error scrambler turned off. Column 604 includes a plurality of time-domain waveforms 606b, 608b, 610b, 612b, and 614b for different control codes when the DTC error scrambler turned on. As shown in the waveforms of column 602, when the DTC error scrambler is turned off (e.g., no randomization is applied), each of the waveforms are periodic. As shown in the waveforms of column 604, when the DTC error scrambler is turned on (e.g., randomization is applied), each of the waveforms appears aperiodic and noise-like.

Waveforms 606a and 606b illustrate the effect of the DTC error scrambler on D₁+D₂ (e.g., D_{frac}). Waveforms 608a and 608b illustrate the effect of the DTC error scrambler on D₁. Waveforms 610a and 610b illustrate the effect of the DTC error scrambler on D₂. Waveforms 612a and 612b illustrate the effect of the DTC error scrambler on inj_polar (e.g., whether the reference clock is injected at a rising or falling edge of the DCO). When the DTC error scrambler is on (e.g., the randomization algorithm is applied), the reference clock is randomly injected at either the rising or falling edge. When the DTC error scrambler is turned off, the reference clock may only be injected at a single polarity (e.g., only at the rising edge or the falling edge). Waveforms 614a and 614b illustrate the effect of the DTC error scrambler on the injection error. As shown in waveform 614a, when the DTC error scrambler is turned off, the injection error may be periodic. As shown in waveform 614b, when the DTC error scrambler is turned on, the injection error may be or appear to be random or noise-like.

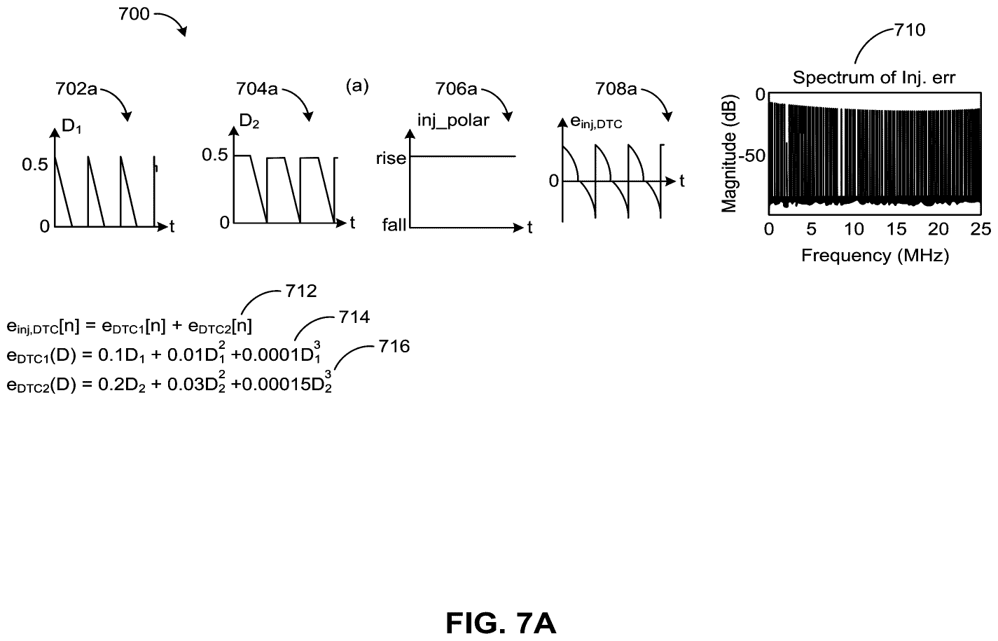

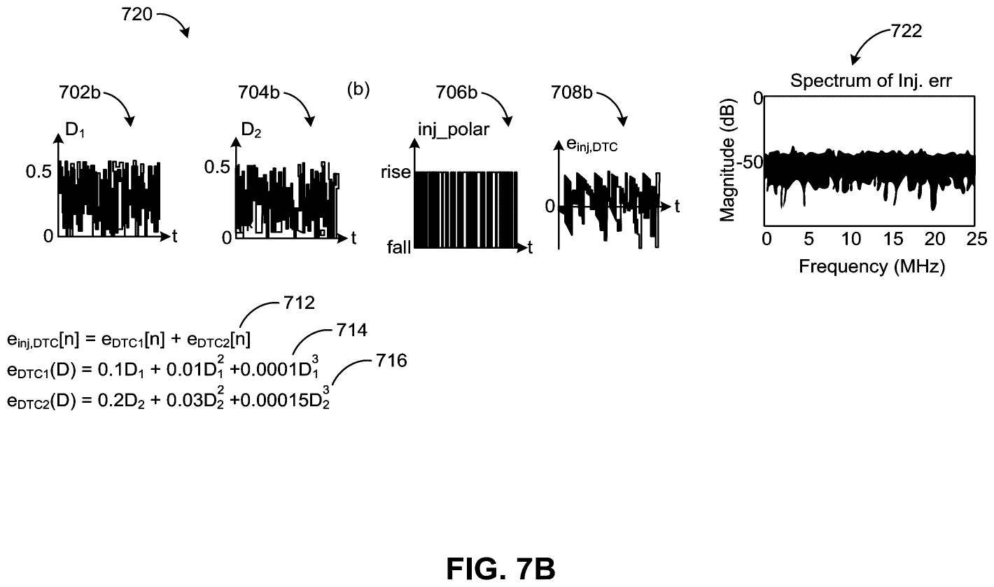

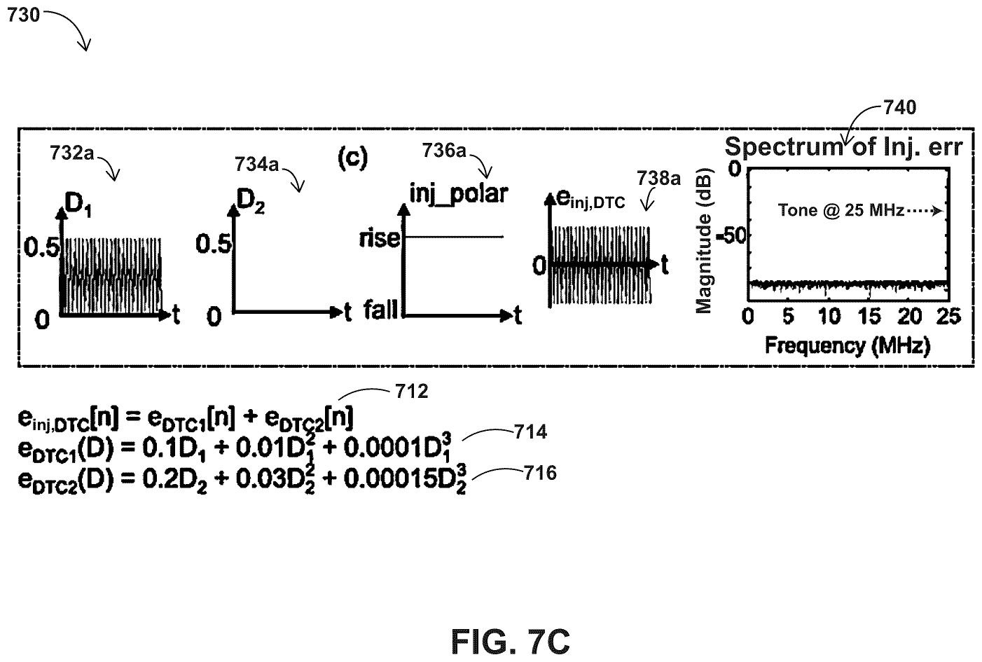

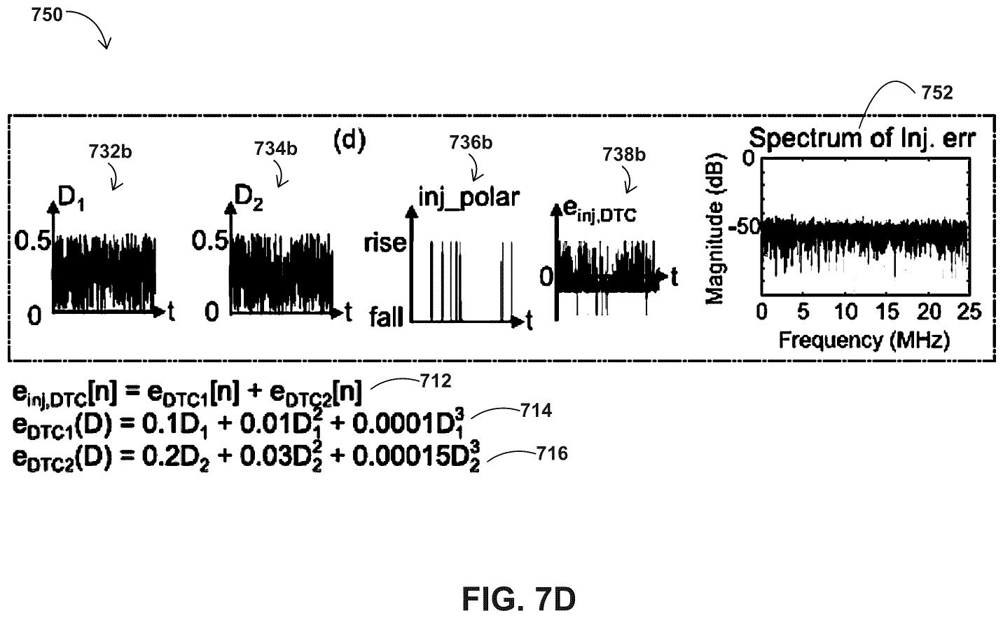

A delay mismatch between the rising and falling injection paths of either one of the DCO (e.g., the DCO 209) or a non-50%-duty-cycle DCO waveform may cause a phase error, referred to as injection-polarity error, in the DCO output. This may increase jitter. FIGS. 7A through 7D show the injection errors and describe them in greater detail.

Referring now to FIGS. 7A through 7D, waveforms of the DTC control codes and injection errors under DTC offset, gain, and INL errors are shown, according to exemplary embodiments. Specifically, FIGS. 7A and 7C depict waveforms without an effect of the DTC error scrambler 250, and FIGS. 7B and 7D depict waveforms with the effect of the DTC error scrambler 250, according to example embodiments.

FIG. 7A illustrates an embodiment 700 in which the DTC error scrambler is in an off configuration and frac (FCW)=½⁷. Waveforms 702a and 704a indicate that D₁ and D₂, respectively, are periodic signals. Waveform 706a indicates that the polarity of the injection of the reference signal is always at the rising edge of the DCO. Waveform 708a indicates that the injection error is periodic. Waveform 710 shows a frequency versus magnitude spectrum plot of the injection error. As shown, waveform 710 includes a plurality of spurs as a result of the periodic injection error.

Equation 712 indicates an injection error of the system due to DTC errors (e.g., including the first and second injection error DTCs), represented as e_{inj,DTC}[n]=e_{DIC1}[n]+e_{DTC2}[n]. Equation 712 may be used to plot the injection error waveform (represented in FIGS. 7A-7D as waveforms 708a, 708b, 738a, and 738b, respectively). An overall injection error of the system eᵢₙⱼ[n] may include only the component due to DTC errors, represented as e_{inj,DTC}[n] if only DTC errors are considered. Equation 714 represents an error of the first injection DTC. The equation 714 may be used to plot the D₁ waveform (represented in FIGS. 7A-7D as waveforms 702a, 702b, 732a, and 732b, respectively). In an exemplary embodiment, equation 714 may be represented as e_{DTC1}(D)=0.1D₁+0.01D₁²+0.0001D₁³. Equation 716 represents an error of the second injection DTC. The equation 716 may be used to plot the D₂ waveform (represented in FIGS. 7A-7D as waveforms 704a, 704b, 734a, and 734b, respectively). In an exemplary embodiment, the equation 716 may be represented as e_{DTC2}(D)=0.2D₂+0.03D₂²+0.00015D₂³. The values in equations 714 and 716 may vary based upon various factors (e.g., whether the reference clock is injected at the falling or rising edge, what proportion of the totally delay is based on the first DTC and the second DTC, variability in fabrication of circuit etc.). As will be shown in FIGS. 7B through 7D, the equations 712-716 may remain constant independent of whether the DTC error scrambler is in an on configuration or an off configuration and independent of whether a frac (FCW) value.

FIG. 7B illustrates an embodiment 720 in which the DTC error scrambler is in an on configuration and frac (FCW)=½⁷. Waveforms 702b and 704b indicate that D₁ and D₂, respectively, appear as noise or noise-like signals, as opposed to periodic signals as in waveforms 702a and 704a. Waveform 706b indicates that the polarity of the injection of the reference signal is randomized between injection at the rising edge and the falling edge of the DCO. Waveform 708b indicates that the injection error is random and noise-like, as opposed to the periodic injection error shown in waveform 708a. Waveform 722 shows a frequency versus magnitude spectrum plot of the injection error. As shown, waveform 722 appears as noise or a noise-like signal rather than the spurs appearing in the waveform 710 when the DTC error scrambler is off. Since both D₁[n] and D₂[n] are randomized between 0 and 0.5, the code-dependent DTC errors may effectively become noise when the DTC error scrambler is in the on configuration. This may indicate that equal or near-equal energy is distributed across the frequencies, and that the injection error may not generate fractional spurs at a PLL output. Further, the injection error may exhibit white noise behavior. Specifically, the injection error may have a constant expected value over time and an autocovariance function of the injection error may be zero when comparing the injection error to a version of the injection error with a non-zero cycle shift.

FIG. 7C illustrates an embodiment 730 in which the DTC error scrambler is in an off configuration and frac (FCW)=½. Waveforms 732a and 734a indicate that D₁ and D₂, respectively, are periodic signals. Waveform 736a indicates that the polarity of the injection of the reference signal is always at the rising edge of the DCO. Waveform 738a indicates that the injection error is periodic. Waveform 740 shows a frequency versus magnitude spectrum plot of the injection error. As shown, waveform 740 includes a spur as a result of the periodic injection error. In various embodiments, the frequency at which the spur occurs may correspond to a frequency of the reference clock and/or may be based on the frac (FCW) value. For example, in embodiment 730, the reference clock signal may have a frequency of 50 MHz, and the spur in the waveform 740 may occur at 25 MHz. Embodiment 730 may be similar or exhibit similar properties to the embodiment described with respect to FIG. 7A.

FIG. 7D illustrates an embodiment 750 in which the DTC error scrambler is in an on configuration and frac (FCW)=½. Waveforms 732b and 734b indicate that D₁ and D₂, respectively, appear as noise or noise-like signals, as opposed to periodic signals as in waveforms 732a and 734a. Waveform 736b indicates that the polarity of the injection of the reference signal is randomized between injection at the rising edge and the falling edge of the DCO. Waveform 738b indicates that the injection error is random and noise-like, as opposed to the periodic injection error shown in waveform 738a. Waveform 752 shows a frequency versus magnitude spectrum plot of the injection error. As shown, waveform 752 appears as noise or a noise-like signal rather than the spurs appearing in the waveform 740 when the DTC error scrambler is off. Embodiment 750 may be similar or exhibit similar properties to the embodiment described with respect to FIG. 7B.

As shown in FIGS. 7A-7D, the systems and methods described herein may be utilized both in implementations where a frequency setting deviates from (e.g., is far from) an integer value of the FCW and in implementations where the frequency setting is close to or near an integer value of the FCW. For example, FIGS. 7A and 7B illustrate an embodiment in which frac (FCW) is equal to ½⁷ (e.g., a small number) and FIGS. 7C and 7D illustrate an embodiment in which frac (FCW) is equal to ½ (e.g., a large number)

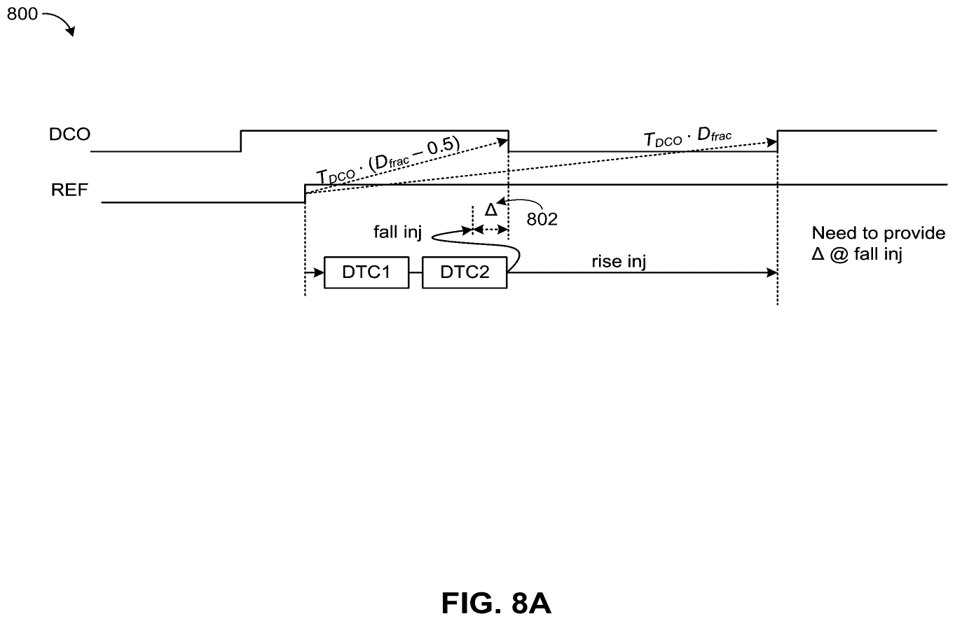

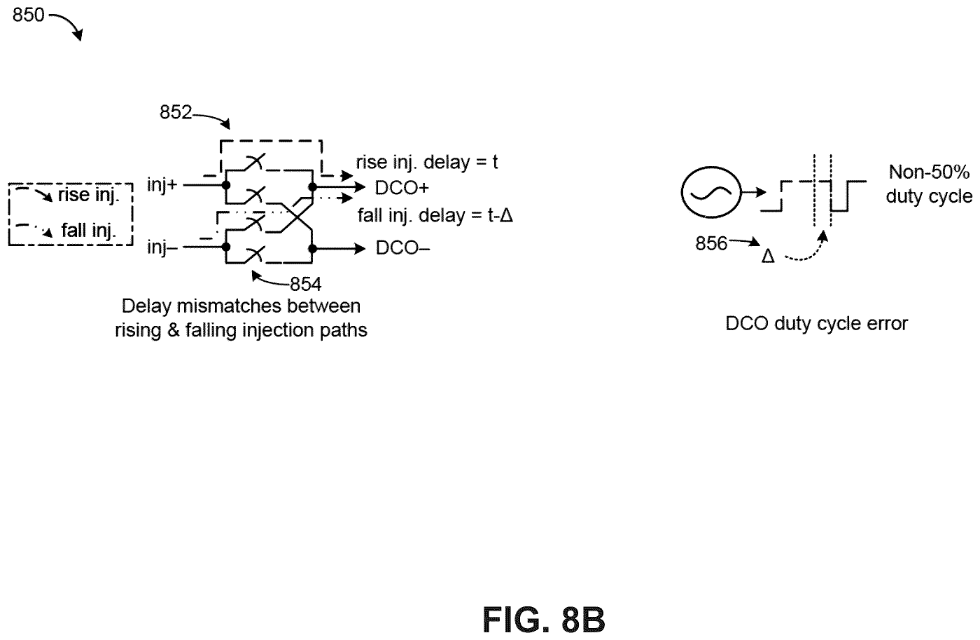

Referring now to FIGS. 8A and 8B, block diagrams 800 and 850 are shown that indicate the timing of and example causes of injection polarity error, respectively, according to an example embodiment. As discussed above, the injection error scrambling technique involves performing reference injections at both DCO rising and falling edges. A discrepancy in the timing between these rising and falling injections may lead to a phase error at the DCO output, which may be referred to as an injection-polarity error. For example, referring to FIG. 8A, as shown in diagram 800, a time delay, indicated by delta 802, may occur between injecting a reference signal to the DCO at the rising edge and the falling edge of the DCO. Thus, the total injection error may include a component from DTC errors as well as from injection-polarity errors. FIGS. 8A and 8B illustrate that injection polarity error may be often by a delay mismatch between the rising and falling injection paths or a non-50% duty cycle DCO waveform. For example, as shown in FIG. 8B, a timing mismatch may exist between the injection path associated with the first DTC and the injection path associated with the second DTC. This may be caused by the use of separate switches, shown as switches 852 and 854, to control the injection polarity for each of the injection DTCs. The injection-polarity error may be modeled by a number series eₚ[n]:Δₚ[n]=0 when injecting at the DCO rising edge (inj_polar=1) and eₚ[n]=Δ when injecting at the DCO falling edge (inj_polar=0). Δ, shown in FIG. 8B as delta 856 is the magnitude of the injection-polarity error. The injection-polarity error may be modeled, in an exemplary embodiment, as occurring only during falling edge injection, with the rising edge injection serving as a reference point.

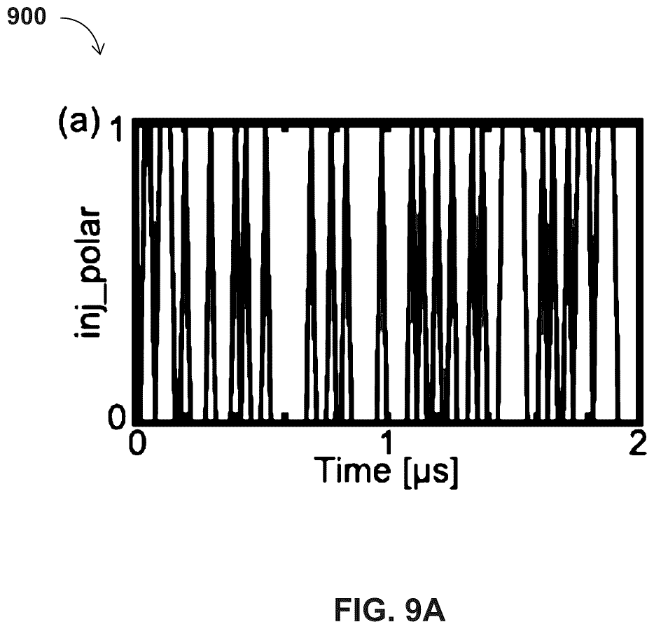

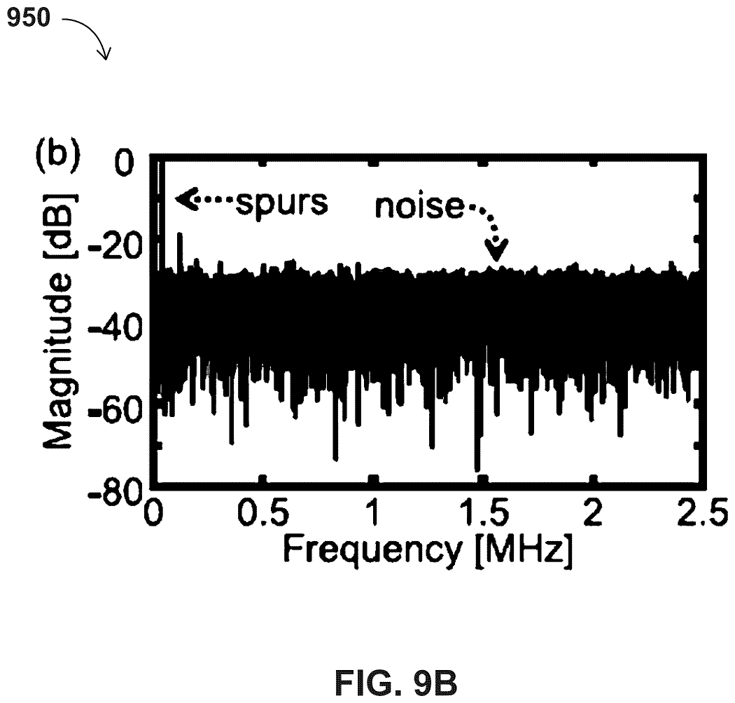

FIG. 9A shows a time-domain waveform 900 of the injection polarity control code, inj_polar, according to an example embodiment. FIG. 9B shows a power spectral density 950 of the inj_polar code, according to an example embodiment. The waveform 950 may be a Fourier transform of the time-domain waveform 900. The inj_polar control code may be proportional to the injection polarity error. The presence of both harmonic tones and noise in the spectrum 950 may indicate that the injection-polarity error elevates both the noise floor and fractional spur levels of the DCO output spectrum, which may be the result of stochastic and periodic components in the error sequence. The periodic component may be attributed to unequal probabilities of rising and falling edge injections for different D_{frac} values.

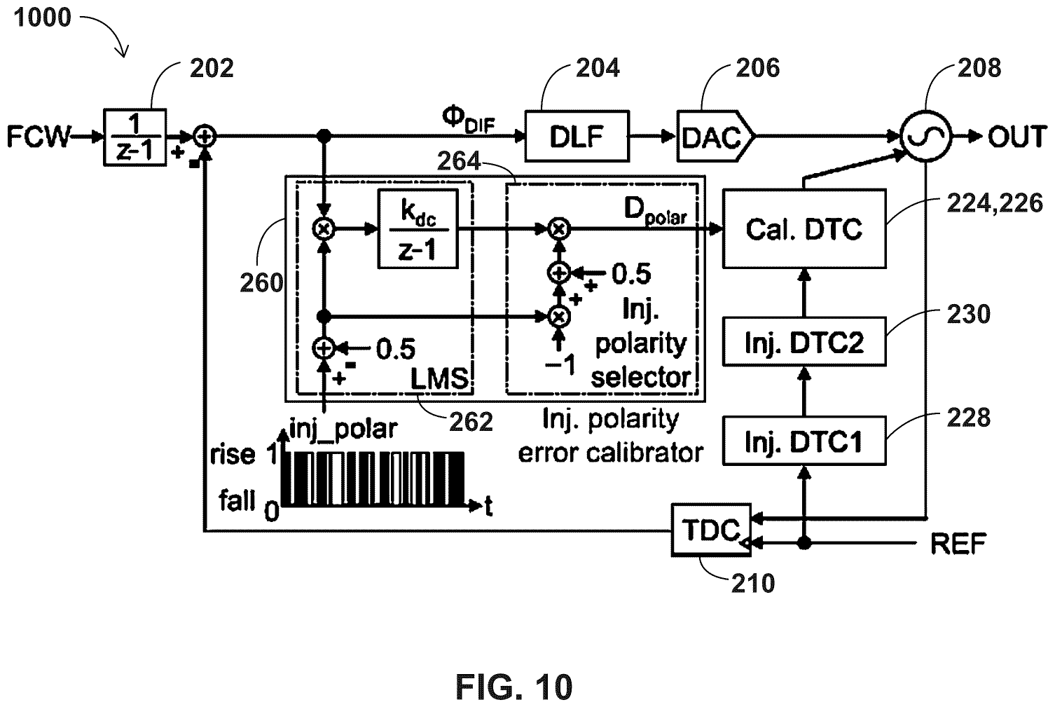

Referring now to FIG. 10, a block diagram of the background error compensator 260 is shown, according to an example embodiment. To mitigate the elevated noise and spur levels caused by the DTC error scrambler, the background error compensator may be implemented, as shown in FIG. 10. The circuit diagram 1000 illustrates an embodiment of the PLL 200 with the background error compensator 260 emphasized. As shown, the background error compensator 260 may be or include a least mean square (LMS) filter 262 and an injection polarity selector 264. The LMS filter 262 may include a LMS algorithm. The background error compensator 260 may use the LMS algorithm to estimate a phase error by correlating an input of the DLF input 204, represented as ϕ_{DIF}, with the injection-polarity control code, represented as inj_polar. In some embodiments, the injection-polarity selector 264 may select which polarity (e.g., rising edge or falling edge) to calibrate. For example, the injection-polarity selector 264 may enable a calibration DTC delay exclusively when injecting at the falling edge. The output of the background error compensator 260 may control the calibration DTCs, shown as Cal. DTCs 226 and 228, to directly subtract the phase error from the output of the injection DTCs 222 and 224. In various embodiments, the background error compensator 260 may reduce a fractional spur level. For example, the background error compensator 260 may reduce the fractional spur level by 6 dB.

FIGS. 11-15 show a background delay equalizer (e.g., the background delay equalizer 240) for calibrating DTC errors. In various embodiments, the background delay equalizer 240 may be of a certain degree or order (e.g., third degree, fourth degree, etc.). The Background delay equalizer 240 described herein may be a third order background delay equalizer. However, it should be understood that the exemplary embodiments described herein are not limited to third-order background delay equalizers. As described herein, the injection error scrambling scheme described in FIGS. 3-10 may mitigate spurs due to injection errors. To lower overall jitter with a low implementation overhead, a dominant component of the DTC error may be corrected. For example, a component causing an amount of error above a certain threshold amount (e.g., causing a majority of the error, causing the largest percentage of error, etc.)

Referring now to FIG. 11, a block diagram 1100 showing digital-to-time converter transfer functions with digital-to-time converter errors is shown, according to an exemplary embodiment. As shown in FIG. 11, the DTC error may be approximated as a polynomial function. The function 1102 may represent an ideal, linear transfer function of the delay. The function 1104 may represent a real, non-linear transfer function. The area 1106 may represent the error corresponding to the DTC control code as a result of the non-idealities of the real transfer function 1104 that cause the real transfer function 1104 to deviate from the ideal transfer function 1102. The real transfer function 1104 of the DTC may deviate from the ideal transfer function 1102 due to variations in process, voltage, and/or temperature (PVT). This deviation (i.e., DTC errors e_{DTC}), may cause a phase error (i.e., injection error eᵢₙⱼ[n]) during reference injection operations. The DTC errors may disturb operation of the PLL and degrade performance. In various embodiments, error caused by the DTC may be represented by the equation 1106. As shown, the total DTC error e_{DTC} may be determine by subtracting the ideal transfer function 1102 from the real transfer function 1104.

The DTC error may also be represented as a polynomial function including a plurality or terms of varying orders. For example, the error may be represented as e_{DTC}=a₀+a₁D+a₂D²+a₃D³+a₄D⁴+ . . . . In some embodiments, the error may be a third order delay equalizer such that the equation includes the zeroth, first, and second order. Thus, the error may be represented as E_{DTC}=a₀+a₁D+a₂D²+a₃D³. Coefficients of each of a zeroth-, first-, and higher-order (e.g., second, third, etc.) term may correspond to a DTC offset, a DTC gain, and INL errors, respectively. In some embodiments, zeroth- to third-order coefficients may be dominant, and higher-order terms may have a minimal impact on the jitter. As such, higher-order terms may be negligible and therefore not included in the equational representation of the error. In various embodiments, term 1108 may be a₀, which corresponds to a zeroth-order term and represents a constant delay difference. a₁D[n] may corresponds to a first-order term. Term 1110 may be a₁, which may denote a gain error. D or D[n] may represent the DTC control code. In various embodiments, D[n] is normalized within [0,1]. Terms 1112 may be a₂, a₃, a₄, etc. (e.g., higher order terms) that may represent the delay difference caused by the INL errors of the DTC. This may form the errors that depend on higher order terms of D[n].

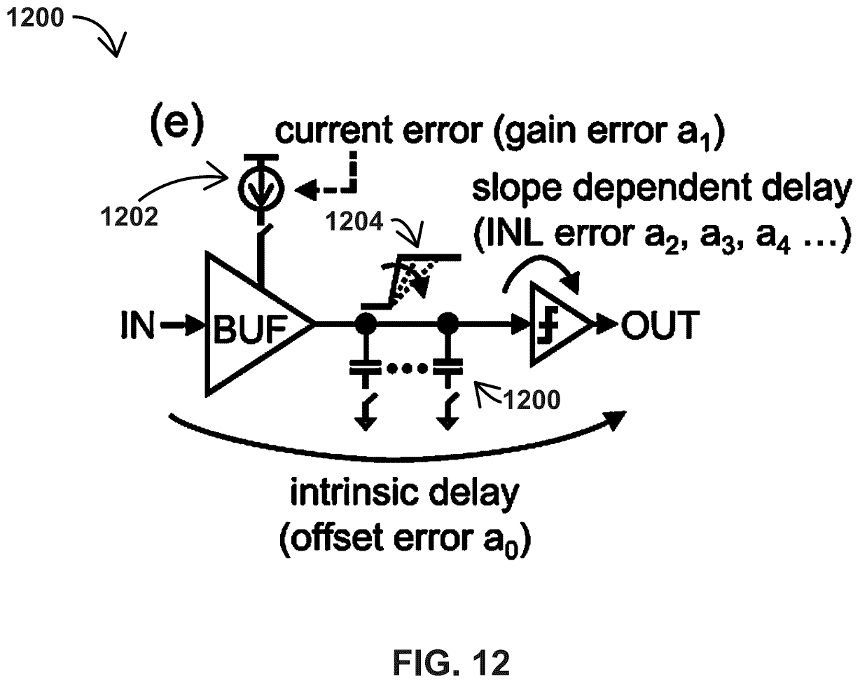

Referring now to FIG. 12, a circuit diagram 1200 illustrating physical mechanisms underlying DTC errors are shown, according to an exemplary embodiment. The physical mechanisms described with respect to FIG. 12 may be examples only and are not intended to be limiting in any way. According to the embodiment of FIG. 12, a representative embodiment of DTC that uses a current-starved inverter with switched capacitors to tune the delay is assumed. It should be understood that the circuit may be represented using additional or alternative components. As shown in FIG. 12, an offset error (represented in FIG. 11 by a₀) may arise or result from an intrinsic delay of the injection path 220, which may include a delay of all the circuits or components in the injection path 220 without switched capacitors 1206 that create a tunable delay. Additionally, variability of the current source 1202 may change or alter the current used to charge the switched capacitor array, generating a DTC gain error (represented in FIG. 11 by a₁). The delay of a crossing detector (e.g., an inverter stage) may change or alter due to a varying ramp slope 1204 when charging the switched capacitor array for different DTC control codes, resulting in the DTC INL error (represented in FIG. 11 by a₂, a₃, etc.).

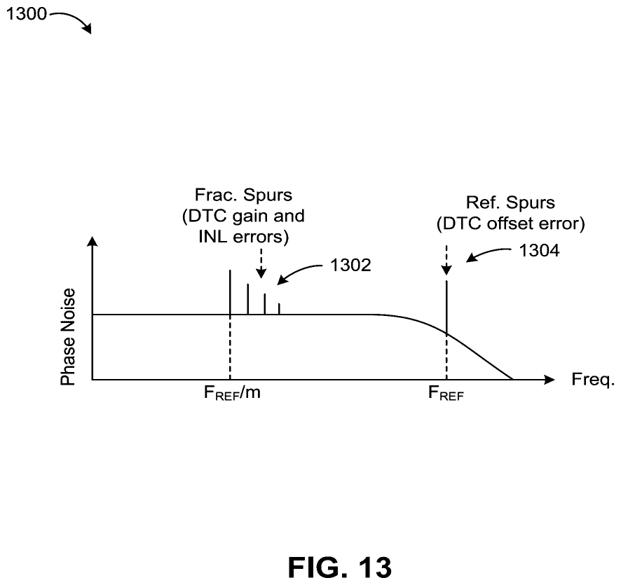

Referring now to FIG. 13, an output spectrum (e.g., a frequency versus phase plot 1300) of the PLL 200 with DTC errors is shown, according to an exemplary embodiment. Specifically, the frequency versus phase plot 1300 illustrates an impact of various types of DTC errors on the spectrum of the PLL (e.g., the PLL 200). In various embodiments, the DTC control code D[n] may exhibit periodic behavior over time. As a result, the code-dependent injection error may also appear periodically. The DTC offset error may affect the oscillator 208 of the PLL 200 with a frequency of the reference clock (e.g., the reference signal 221) and may predominantly degrade reference spurs. That is, when a DTC offset error exists in the PLL 200, a spurious tone 1304 may occur and appear in the plot 1300. Further, the DTC gain error and the INL error may repeat at a fraction of f_{REF}. As a result, the DTC gain error and INL error may cause or worsen fractional spurs, shown as fractional spurs 1302 on the plot 1300.

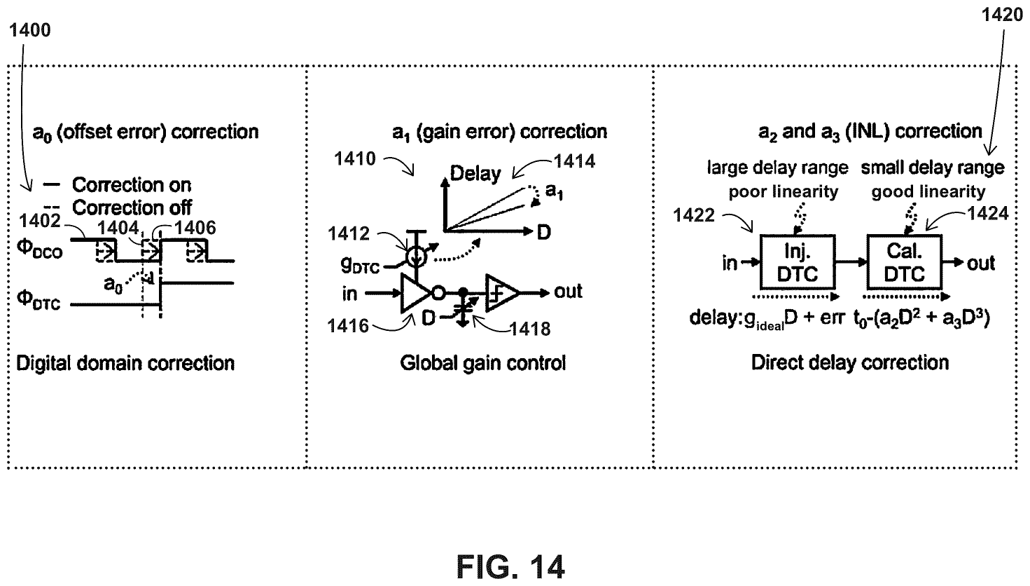

Referring now to FIG. 14, a block diagram 1400 for performing a multipoint correction of a background delay equalizer (e.g., the delay equalizer 240) is shown, according to an example embodiment. The background delay equalizer 240 may be implemented to correct the DTC error at multiple points of the PLL (e.g., the PLL 200). In various embodiments, a background delay equalizer of a greater or lesser order may be used. For example, the PLL 200 may utilize a fourth order background delay equalizer. As shown at process 1401, a DTC offset error may be corrected. At process 1401, the DTC offset error may be static. The DTC offset error may be corrected in the digital domain, for example, by skewing an RO phase. For example, a face of the DCO 209 may be tuned to align with the DTC phase. For example, as shown at process 1401, a rising edge 1404 of the DCO phase 1402 may occur before the phase of the DTC, causing the offset error, shown as offset 1406. Tuning the DCO 209 such that the DCO phase 1402 aligns with the DTC phase may eliminate or mitigate the offset error. As such, skewing the RO phase may avoid or mitigate a physical delay for the DTC-offset error correction.

As shown at process 1410, the DTC gain is globally controlled by changing the current source of the buffer in the DTC. For example, a current source 1412 may be implemented in the circuit to correct a gain of the DTC. As shown by the transfer function 1414, the addition of the current source 1412 may reduce a slop of the transfer function, thus correcting a gain error/In some embodiments, gain control may be performed using a current DAC. Gain error correction may be referred to as “global gain control” due to the fact that addition of the current source 1412 in the circuit may cause a change in the gain for all of the control code in the circuit (e.g., the slope of the transfer function may change globally). In various embodiments, the DTC gain may be controlled by changing a capacitive loading 1418 of a DTC buffer 1416, thus occupying a larger area of the circuit. As a result, one or more switched capacitors may be used to control the DTC gain error.

As shown at process 1420, the DTC INL error (e.g., second-, third-, and/or higher-order terms) may be directly corrected via one or more cascaded calibration DTCs 1424. In various embodiments, the DTC INL error may include higher order terms, such as a fourth-order term or greater. As shown at process 1420, an injection error DTC 1422 may have a large delay range, resulting in poor linearity compared to the calibration DTC 1424. The calibration DTC 1424 may have a smaller delay range, resulting in improved linearity. The calibration DTCs 1424 may not need to correct the gain error as a result of the global gain tuning and digital domain offset compensation (e.g., the processes 1401 and 1420 correct the offset error and gain error, respectively). As such, the full range of the calibration DTC 1424 may be small (e.g., several picoseconds). This may result in a short delay line and a negligible nonlinearity and jitter contribution from the calibration DTCs 1424.

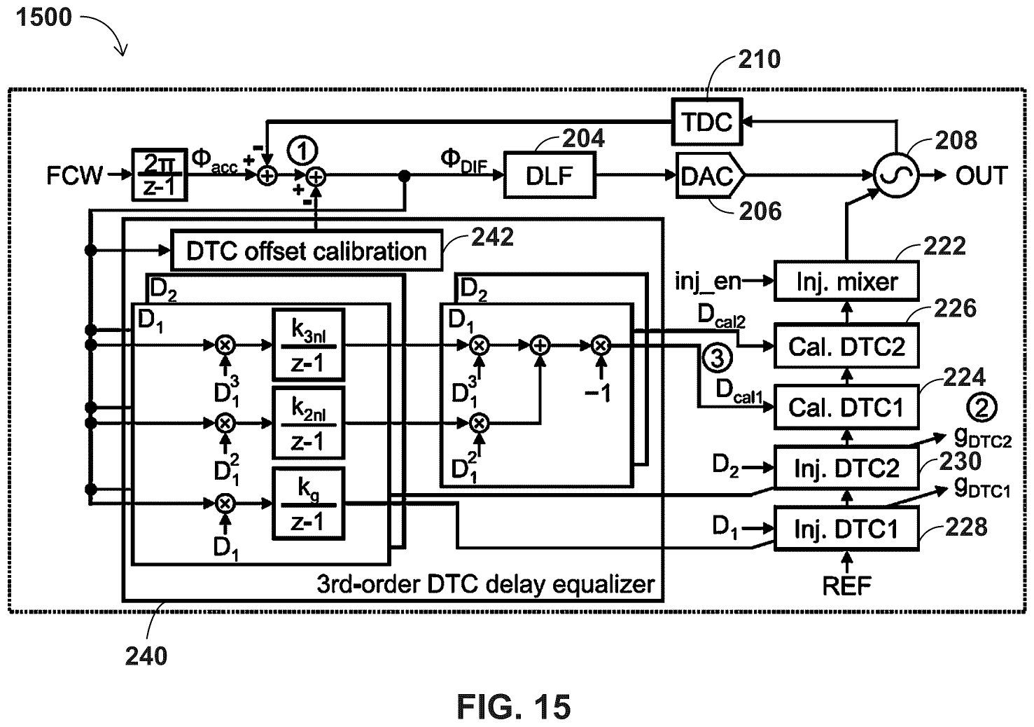

FIG. 15 is a circuit diagram 1500 illustrating an implementation of the background delay equalizer 240. The background delay equalizer 240 may estimate or determine different DTC-error sources (e.g., the offset error, the gain error, and/or the INL error) in the background so that variations in process, voltage, temperature, etc. may be measured. A signal may enter the oscillator 208 from the injection path 220. The signal may exit a phase of the oscillator 208 and enter the TDC 210 to convert the signal from an analog signal to a digital signal. That is, the TDC 210 may convert phase information of the oscillator (e.g., an analog signal) to a digital signal. At node 1502, the now digital signal may enter the background delay equalizer 240. The background delay equalizer may be or include an LMS filter. That is, the DTC gain and INL errors may be estimated using LMS algorithms. In some embodiments, the DTC offset error may be extracted with injection squelching. The LMS algorithms may extract error components from different error sources. Upon convergence of the LMS filter, the error may become stable, allowing the error to be corrected. Specifically, the LMS algorithms may correlate the DLF 204 input ϕ_{DIF}[n] with the different DTC control codes D₁[n] and D₂[n] and the squared and cubed values of D₁[n] and D₂[n]. Two sets of LMS blocks, each corresponding to D₁ and D₂, respectively, may be used to calibrate non-idealities of the injection DTC1 222 and the injection DTC2 224. In various embodiments, each DTC 222 and 224 may cover 0.5 T_{DCO} separately. The use of the two injection DTCs 222 and 224 may be required by the injection error scrambling technique described above with respect to FIGS. 3-10.

Transient settling behavior of different calibrators in the background delay equalizer 240 may be determined. For example, the transient settling behavior may be determined using a Verilog AMS simulation. In various embodiments, calibrators in the background delay equalizer 240 may settle within a certain value (e.g., 2 milliseconds) with a remaining error of less than a certain value (e.g., within less than 1 LSB) of the calibration DTC (e.g., around 150 fs) under the reference clock 221 (e.g., a 50-MHz reference clock). In various embodiments, each individual calibrator may reach a correct value as long as an adaptive step is set to be small enough.

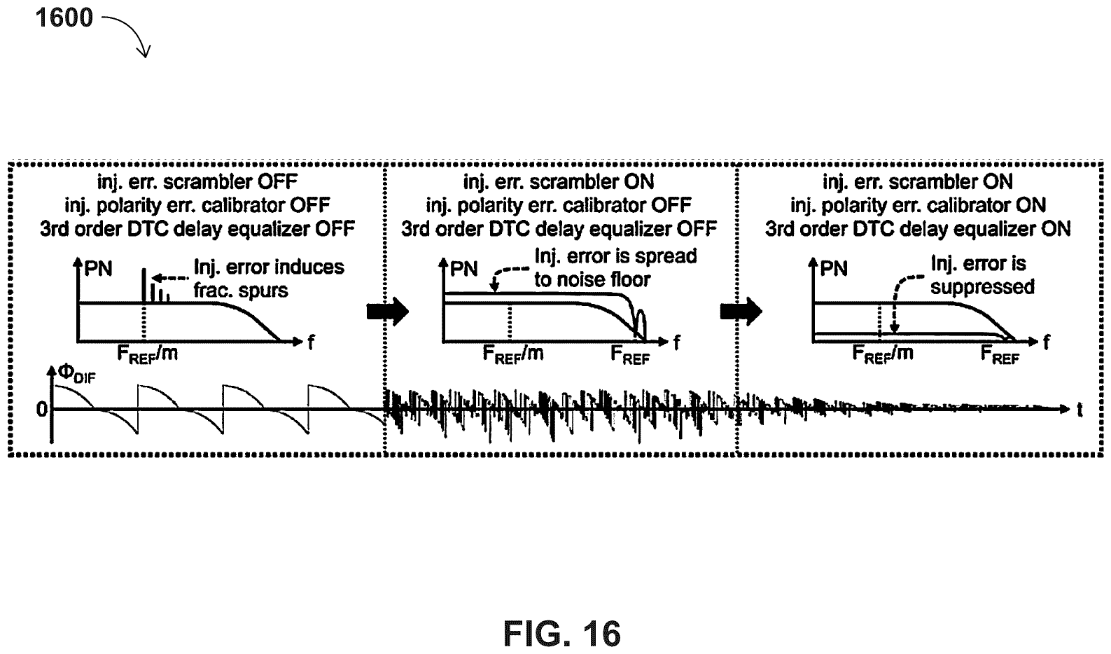

FIG. 16 shows a block diagram 1600 illustrating an effect of the DTC error scrambler 250 and the background delay equalizer 240 in both the time domain and the frequency domain, according to an exemplary embodiment. Block 1610 shows the time domain and the frequency domain when all of the DTC error scrambler 250, the background error compensator 260, and the background delay equalizer 240 are OFF. A delay mismatch between the rising and falling injection paths of either one of the DCO or a non-50%-duty-cycle DCO waveform may incur or cause a phase error, referred to as injection-polarity error, in the DCO output. This may increase jitter. The background error compensator 260 may estimate the phase error to resolve the problem. For example, the phase error may be estimated via a least-mean-square (LMS) algorithm. The LMS algorithm may minimize a correlation between the DLF input DIF, and the injection-polarity control code, inj_polar. A plurality of cascaded calibration DTCs may be introduced to subtract the phase error at the output of the injection DTCs. As shown in block 1610, the injection error may induce fractional spurs.

Block 1620 shows the time domain and the frequency domain when the DTC error scrambler 250 is ON and both the background error compensator 260 and the background delay equalizer 240 are OFF. The DTC error scrambler 250 may break the periodicity of the injection error and spread the spurious-tones energy to the elevated noise floor.

Block 1630 shows the time domain and the frequency domain when all of the DTC error scrambler 250, the background error compensator 260, and the background delay equalizer 240 are ON. After the background error compensator 260 and the background delay equalizer 240 are enabled, the magnitude of the DTC error is minimized, meaning the injection error is suppressed. A low phase-noise level is achieved. The combination of the injection error scrambling and the background delay equalizer may lead to a low-spur and low-noise performance in a PLL at the same time.

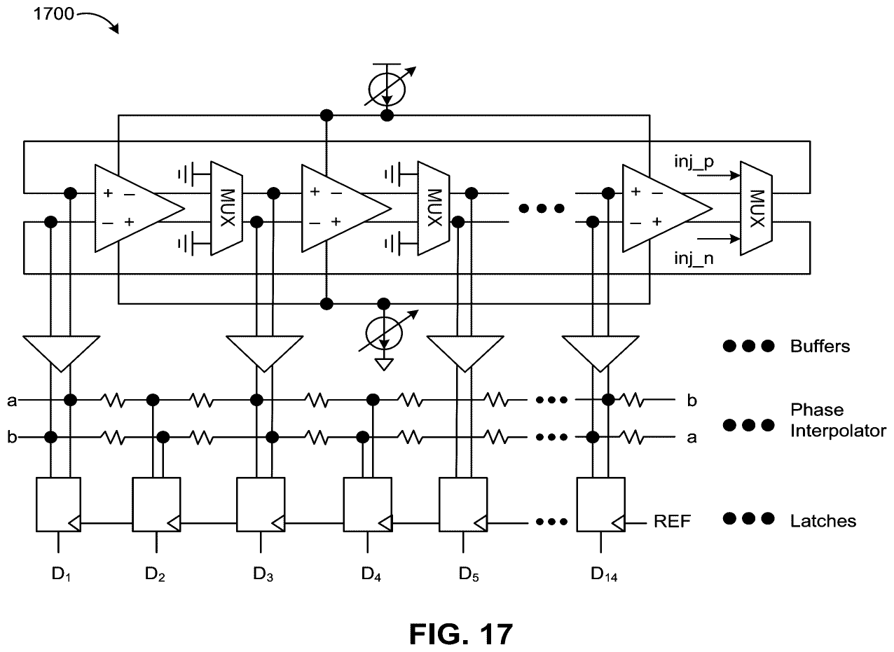

FIGS. 17-24 show an exemplary circuit implementation of a PLL with injection error scrambling and a background delay equalizer. As shown in FIGS. 17-24, the building blocks may include any combination of a pulse window generator (e.g., the pulse window generator 211), the injection path (e.g., the injection path 220), and the DCO (e.g., the DCO 209). A MDLL or PLL may also include other or additional elements. For example, a MDLL or PLL may include an embedded TDC and/or a multiplexer. Additional circuit components that may be implemented are described herein.

As an example, an MDLL may be fabricated in 65 nm complimentary metal-oxide semiconductor (CMOS) having a certain size (e.g., 65 nm). The CMOS may include a certain active area (e.g., 0.23 mm²). Further, digital core and analog blocks may occupy a certain amount of space on the CMOS (e.g., 0.18 mm² and 0.05 mm², respectively). In one example, a total power consumption of the MDLL may be of 13.56 mW from a 1V supply, with 6.16 mW in the analog and 7.4 mW in the digital domain. The MDLL may have an associated frequency tuning range (e.g., 1.0 to 1.8 GHz using a 50 MHz reference clock). Phase noise profiles of the MDLL may be measured at a certain frequency (e.g., around 1.5 GHz with a frequency multiplication ratio of 30+ 1/128). Enabling a background delay equalizer (e.g., a third order background delay equalizer 240) and a background error compensator (e.g., the background error compensator 260) may result in negligible noise-floor elevation due to the scrambled injection error. Enabling the third-order background delay equalizer and the background error compensator may also result in jitter reduction (e.g., >4× rms-jitter reduction) and phase noise reduction (e.g., −116 dBc/Hz phase noise at a 1 MHz frequency offset). Injection error scrambling and the third-order background delay equalizer may also reduce the fractional and reference spur levels by a certain level (e.g., 29 dB and 32 dB, respectively).

In various embodiments, prior to enabling the injection, an integrated rms jitter may be measured to be a certain value (e.g., 14.8 ps from 10 kHz to 10 MHz). Upon enabling the injection and the injection error scrambling scheme, the integrated rms jitter may be reduced (e.g., to 3.32 ps for the same integration bandwidth). Phase noise may also be reducted (e.g., to −102 dBc/Hz at a 1-MHz frequency offset). With the addition of DTC offset and gain error calibration through the third-order background delay equalizer, the integrated rms jitter may decrease further (e.g., to 1.51 ps), and the phase noise may reduce (e.g., −109 dBc/Hz). By applying second-order and third-order DTC error calibration, the integrated jitter and the phase noise may reach lower levels (e.g., 800 fs and −116 dBc/Hz, respectively). When reference injection is applied without any calibration, large spurs may be generated due to DTC errors. After enabling the third-order background delay equalizer, the fractional and reference spurs may be reduced (e.g., by 19 and 32 dB, respectively). In addition, the injection error scrambling scheme may lead to further reduction in the fractional spur level (e.g., by 10 dB). The final performance of fractional and reference spurs may be for example, −67 and −58 dBc, respectively.

FIG. 17 is a circuit diagram 1700 of a DCO and an embedded TDC, according to an example embodiment. The circuit 1700 may include a plurality of multiplexers 1702, a plurality of buffers 1704, a plurality of phase interpolators 1706, and a plurality of latches 1708. In various embodiments, the DCO may be, for example, a seven-stage pseudo-differential current starved RO. The TDC may include an 8-bit integer counter and a 28-phase embedded TDC, for example. The embedded TDC may quantify the phase through DCO internal nodes and interpolation resistors, providing, a time resolution (e.g., around 24-ps time resolution). To mitigate the effect of TDC quantization error, TDC dithering and dither cancellation may be applied to improve DTC error estimation accuracy. The final TDC resolution for DTC error detection may achieve 10-bit, although in various embodiments the embedded TDC resolution may be less than 5-bit.

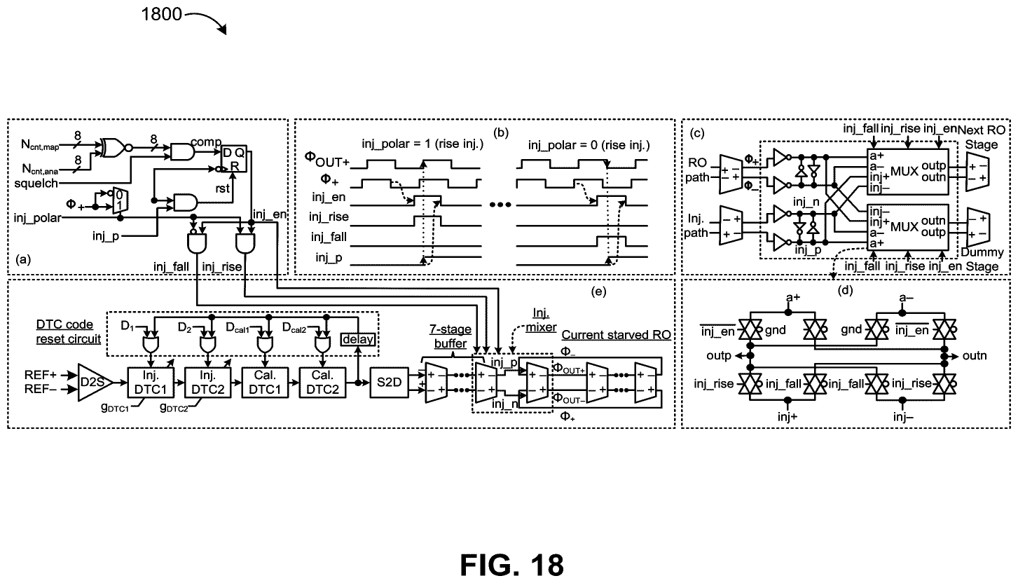

FIG. 18 illustrates a block diagram 1800 of injection path and injection control circuits, according to an example embodiment. A differential reference clock signal (REF+ and REF−) first enters the differential-to-single-ended (D2S) buffer and propagates through injection and calibration DTCs to obtain proper delay tuning. After converting the delayed signal back to differential through the single-ended-to-differential (S2D) buffer, the injection signal passes through a buffer chain of seven delay stages identical to those used in the DCO. The buffer chain may be to shape the injection signal transitions to be similar to those in the DCO so that reducing the reference spurs. The buffer chain connects to the seven-stage pseudo-differential DCO with an injection mixer. The pulse window generator controls the injection mixer to regulate the injection timing and polarity. The following paragraphs describe the building blocks of FIG. 18 in greater detail.

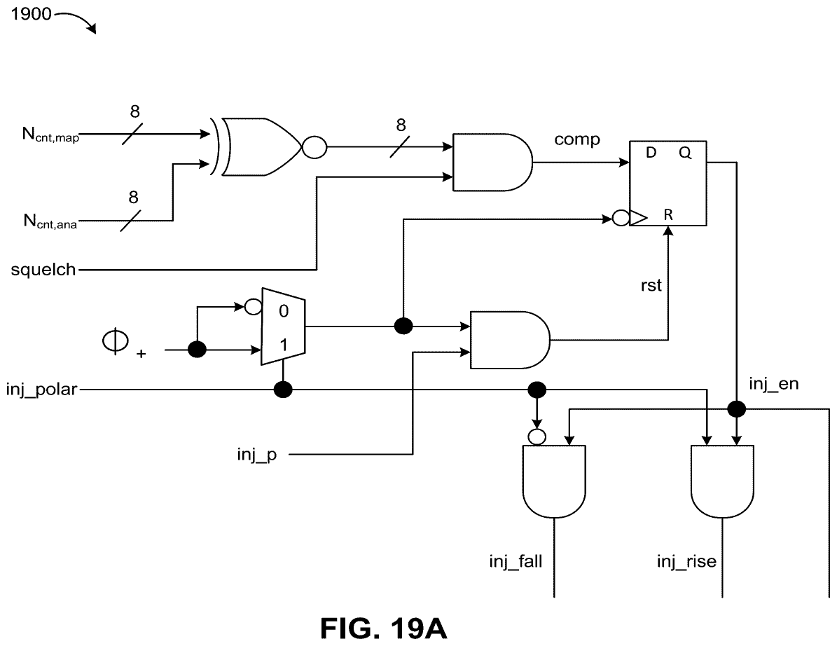

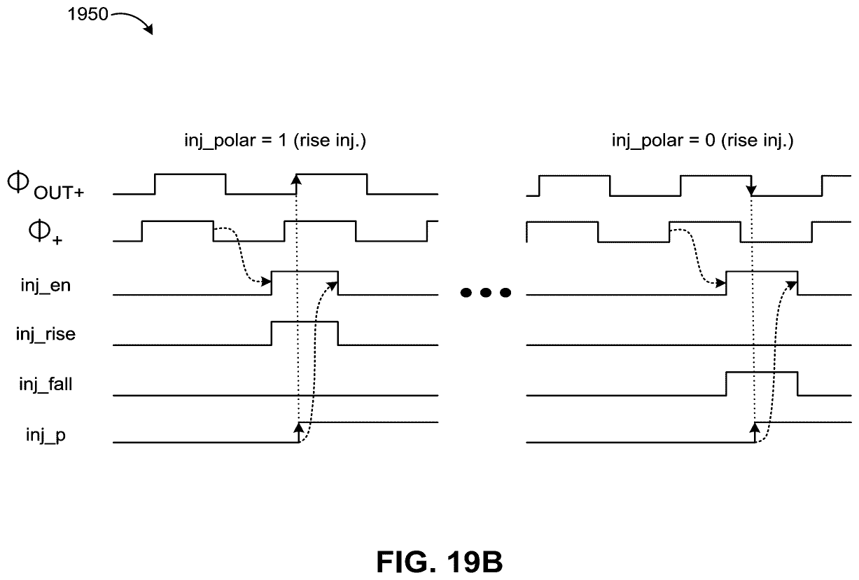

FIGS. 19A and 19B depict a pulse window, according to an example embodiment. The pulse-window signals inj_en, inj_rise, and inj_fall are generated according to the DCO internal node ϕ₊, injection signal inj_p, and injection polarity inj_polar. Specifically, FIG. 19A is a block diagram 1900 of the pulse window generator. FIG. 19B is a timing diagram 1950 of the pulse window generator. Referring to FIG. 19A, an integer counter output N_{cnt,ana} is compared with a pre-calculated value N_{cnt,map} that may be generated from DTC error scrambler, which corresponds to an integer counter code at a next injection event. The input to the D flip-flop (comp) may be set when N_{cnt,map}=N_{cnt,ana}. Inj_en, the injection enabling signal, may then be set high by the falling edge of ϕ+ when inj_polar=1 (i.e., injecting to DCO rising edge) or by the rising edge of ϕ+ when inj_polar=0 (i.e., injecting to DCO falling edge). After the injection, both ϕ+ and inj_p reset the D flip-flop, de-asserting inj_en and allowing the DCO to resume normal oscillation. The signals inj_rise and inj_fall may be generated from inj_polar and inj_en, respectively, to control the signal flow polarity in the injection mixer. The signal squelch, which may gate off the injection operation when high, may be used for DTC offset error detection using injection squelching technique.

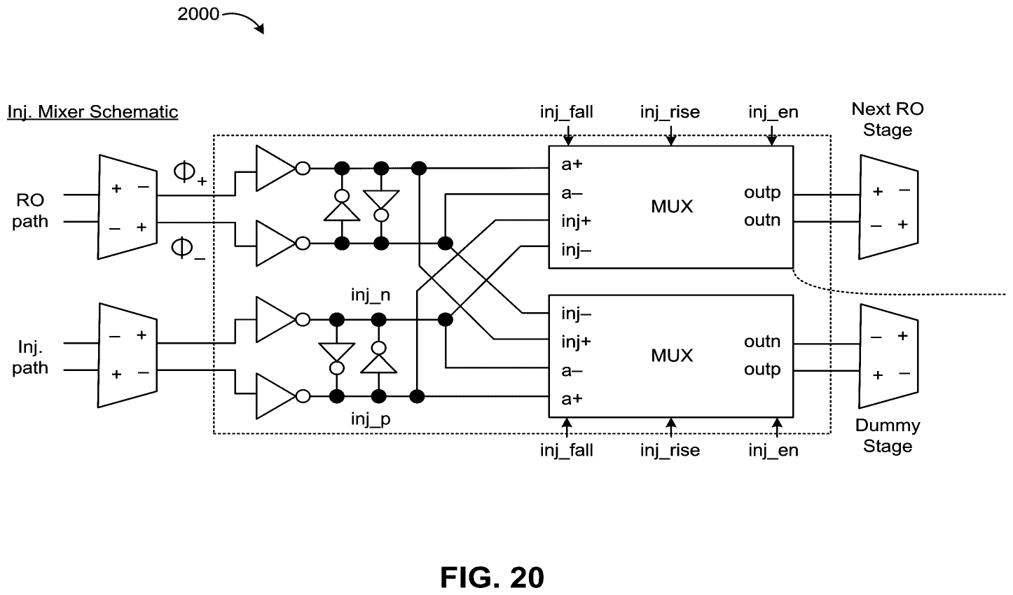

FIG. 20 shows a circuit diagram 2000 of an injection mixer, according to an example embodiment. The injection mixer may perform the injection incident (e.g., injection of the reference signal). The control signals, inj_fall, inj_rise, and inj_en, may be generated from the pulse window generator of FIG. 19A. When inj_en asserts, the RO path may be disabled, and the injection mixer may be ready for reference injection. When inj_rise or inj_fall asserts, reference injection may happen at DCO rising edge or DCO falling edge, respectively. The injection mixer may also include a dummy stage. The dummy stage may minimize a load variation at the injection point and reduce a disturbance to the DCO when reference injection happens, which may result in a lower spur level.

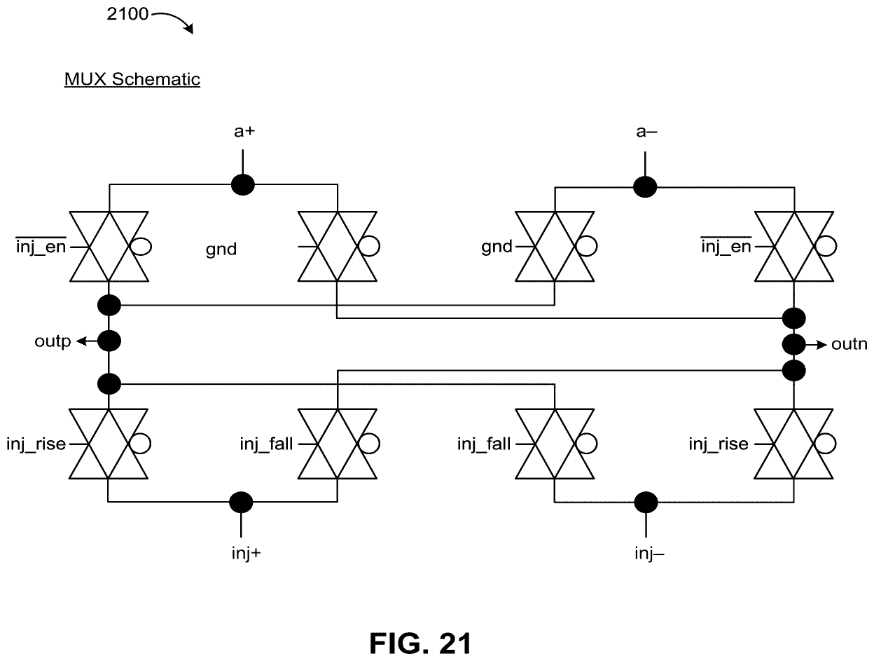

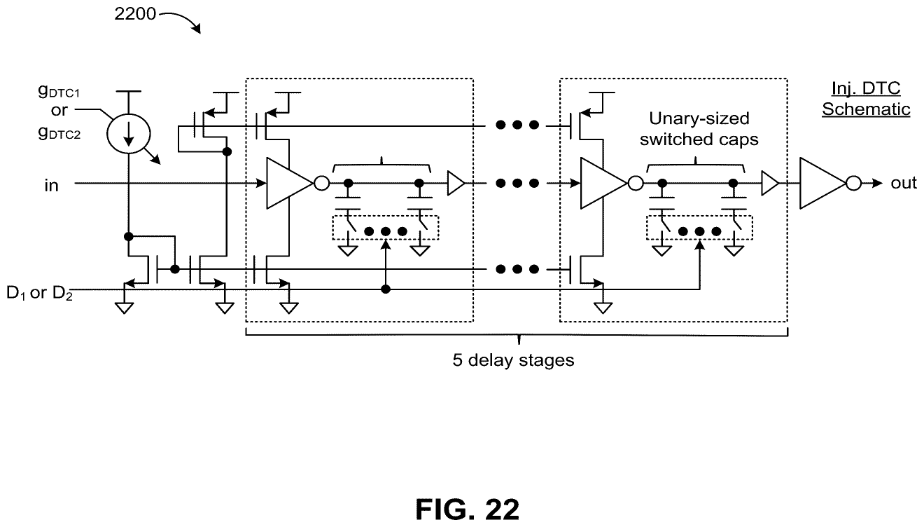

FIG. 21 shows a circuit diagram 2100 of the multiplexer of the injection mixer of FIG. 22, according to an exemplary embodiment. The multiplexer within the injection mixer determines the signal flow of the injection incident.

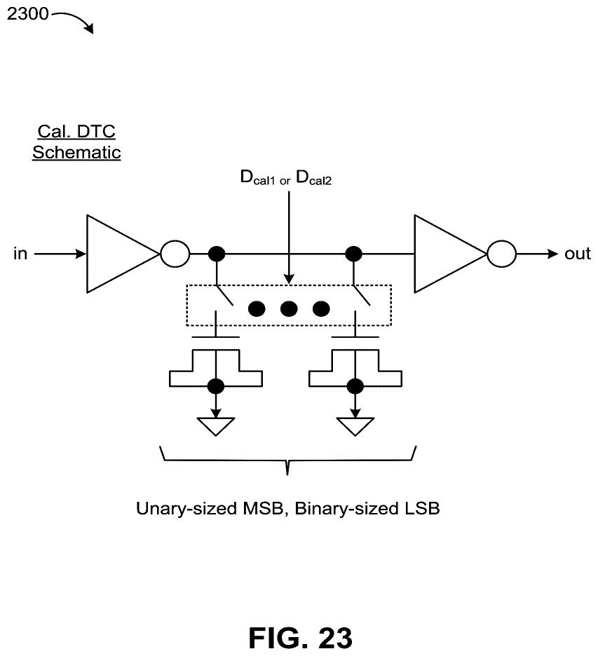

Referring now to both FIG. 22 and FIG. 23, circuit diagrams 2200 and 2300 are shown for an injection DTC and a calibration DTC, respectively, according to example embodiments. The injection and calibration DTCs may be implemented using inverter-based architecture (e.g., for simplicity) and an improved jitter and power trade-off. The DTC-code-reset circuit may assert all DTC control codes after every injection incident with the delayed DTC output through OR gates, which may reduce inter-symbol interference and therefore prevent noise floor elevation.

Referring in more detail to FIG. 22, the injection DTC 2200 shown may include a plurality of delay stages (e.g., five), each having a current-starved inverter with, for example, 64 unary-sized switched capacitor loads. The switched capacitor loads may provide a tunable delay of, for example, around 0.5 T_{DCO}. The DTC control code (D₁ or D₂) may tune the five sets of switched capacitors simultaneously to distribute additional delay and prevent excessive slow transitions, reducing overall jitter. Dynamic element matching may be applied to mitigate mismatch when encoding D₁ or D₂. The gain of the injection DTC may be adjusted by a current DAC (controlled by g_{DTC1} or g_{DTC2}) to tune the current sources and achieve an accuracy of around 400 fs.

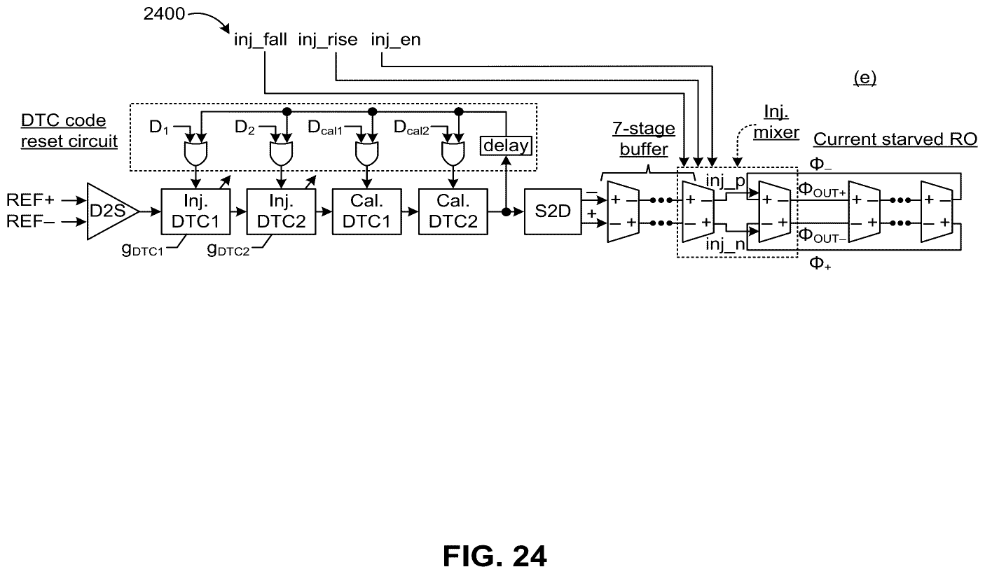

Referring in more detail to FIG. 23, the calibration DTC 2300 is shown. The calibration DTC may have a total tunable delay of, for example, around 10 ps. The calibration DTC may consist of one inverter with switched capacitor loads having, for example, 3-bit unary-sized MSBs and 3-bit binary-sized LSBs for improved linearity. Referring now to FIG. 24, a circuit diagram 2400 is shown, according to an example. Specifically, t the circuit diagram 2400 may be a DTC code reset circuit. The DTC code reset circuit 2400 may assert all DTC control codes after every injection incident with the delayed DTC output through OR gates, thus reducing inter-symbol interference (ISI) and preventing noise floor elevation. According to various embodiments, the DTC code reset circuit may reduce ISI by six times. According to various embodiments, post-layout simulation results may indicate a standard deviation of the DTC delay due to the fact that the ISI is less than 90 fs, which may have an ignorable impact on the total jitter.

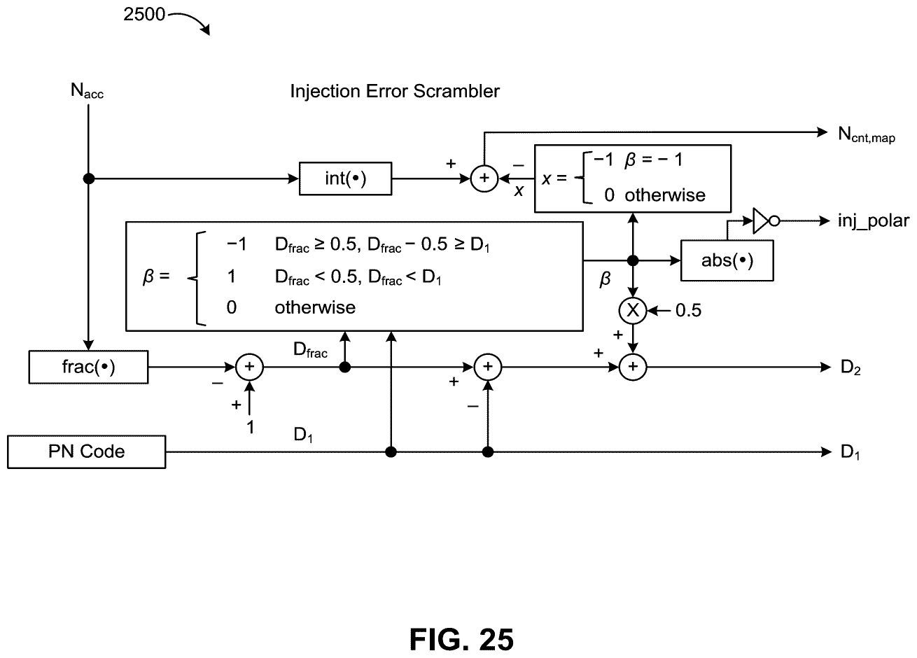

FIG. 25 is a circuit diagram 2500 of a digital portion of the DTC error scrambler. First, D_{frac} is calculated by accumulating FCW. Then, D₁ is generated randomly between 0 and 0.5 from a pseudo-noise (PN) generator. The PN code may repeat its pattern for every 2¹⁶ samples, which may be longer than the maximum repetitive period of D_{frac} (2⁷) as described herein. Depending on the values of D_{frac} and D₁, D₂ may be calculated from the following expression:

$${D}_{2} = {D}_{frac} + 0.5 β - D 1$$

$$β = \{ \begin{matrix}- 1 , & {D}_{frac} \geq 0.5 , {D}_{frac} - 0.5 > {D}_{1} \\ 1 , & {D}_{frac} < 0.5 , {D}_{frac} < {D}_{1} \\ 0 , & otherwise .\end{matrix}$$

When β=0, the reference injection may be performed at DCO rising edge (i.e., inj_polar=1); otherwise, it may be at DCO falling edge (i.e., inj_polar=0). For example, for an arbitrary D_{frac}, both D₁ and D₂ may change from 0 to 0.5 with a uniform probability, and injection errors are fully randomized. The implementation of the DTC error scrambler may have less hardware overhead compared with other approaches, such as, for example, time-invariant-probability modulators (TIPM). For example, TIPM involves two multi-bit multiplication for each operation. In contrast, the DTC error scrambler may not require multi-bit multiplication and may thus save power and area. Also, TIPM cannot work properly when FCW is away from an integer setting (e.g. frac (FCW)=1). Under this setting, the delta-sigma modulator that TIPM relies on enters the state of limit cycle, which will output periodic pattern rather than random pattern, degrading the effectiveness of randomization.

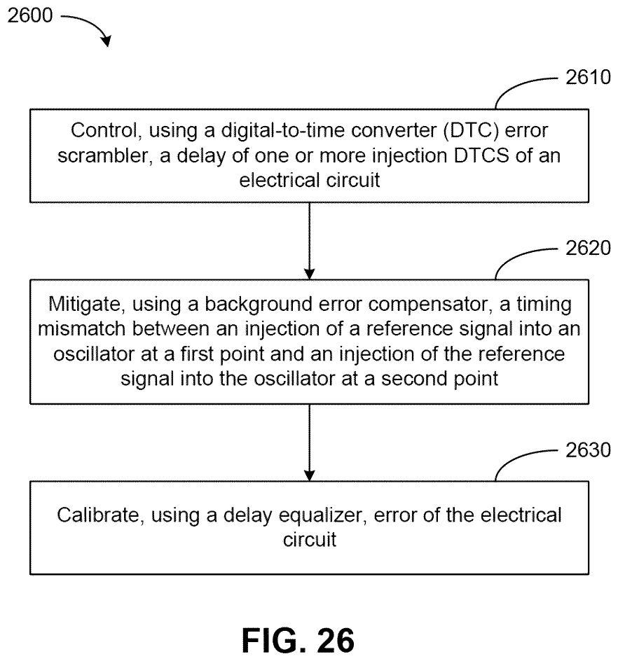

Referring now to FIG. 26, a method 2600 for clock generation is shown, according to an exemplary embodiment. The method 2600 may be performed by one or more components of an electrical circuit. For example, one or more components of the PLL 200 may perform the method 2600. For example, the PLL may include an injection error scrambler, a background error compensator, and a delay equalizer. The PLL may further include one or more of a pulse window generator, an injection path, a digital-controlled oscillator, an injection mixer, an injection digital-to-time converter, or a calibration digital-to-time converter. It should be understood that the steps or processes performed with respect to the method 2600 may be performed in any order and/or combination and the method 2600 is not limited to the order depicted with respect to FIG. 26.

At process 2610, a DTC error scrambler (e.g., the injection error scrambler 250) controls a delay of one or more injection DCTs of an electrical circuit (e.g., the PLL 200). The DTC error scrambler may be configured to randomize error in a DTC (e.g., an injection DTC). The DTC error scrambler may also be configured to suppress spurs of the electrical circuit. The DTC error scrambler may include control code to control a delay of one or more injection DTCs. In various embodiments, a timing mismatch is associated with the DTC error scrambler. As such, the process performed at 2620 may mitigate the timing mismatch. In some embodiments, the pulse window generator may control the timing of an injection of a reference signal and an injection polarity. The reference signal may be configured to periodically refresh a signal of the oscillator to suppress noise in the oscillator. The reference signal may be a low noise signal.

At process 2620, a background error compensator (e.g., the background error compensator 260) mitigates a timing mismatch between an injection of a reference signal into an oscillator at a first point and an injection of the reference signal into the oscillator at a second point. For example, the reference signal may be injected at both a rising edge and a falling edge of the oscillator (e.g., the DCO 209, the oscillator 208, etc.). The background error compensator may mitigate the timing mismatch by extracting, using a filter (e.g., the LMS filter), the timing mismatch between the injection of the reference signal at the first point and the injection of the reference signal at the second point. The background error compensator may further tune control code of the calibration DTC to calibrate a time delay of one or both of the injection of the reference signal at the first point and the injection of the reference signal at the second point.

In various embodiments, randomization from the digital-to-time converter error scrambler performed at process 2610 and calibration from the background delay equalizer performed at process 2620 may occur simultaneously. In some embodiments, the randomization from the digital-to-time converter error scrambler performed at process 2610 and calibration from the background delay equalizer performed at process 2620 occur independently.

At process 2630, a delay equalizer (e.g., the DTC delay equalizer 240) calibrates error of the electrical circuit. The background delay equalizer may include a least mean square filter. In some embodiments, the errors calibrated by the background delay equalizer are any one of a digital-to-time converter offset, a digital-to-time converter gain, or an INL error. In some embodiments, the errors exist at at least one point of a phase-locked loop. The delay equalizer may include a digital domain corrector configured to tune the oscillator to align with a phase of at least one of the injection DTCs to control a first error component (e.g., the DTC offset) of the plurality of error components. As such, the method 2600 may further include tuning a signal of the oscillator to align with a phase of at least one of the one or more injection DTCs to control a first error component of the plurality of error components.

A total delay of the at least one injection DTC may be determined based on a product of a gain of the injection DTC and the control code of the injection DTC. The method 2600 may further include detecting a DTC delay by extracting one or more error components of one or more error sources. The delay equalizer may further include a current source configured to control a second error component (e.g., the DTC converter gain) of the plurality of error components. As such, the method 2600 may further include controlling a current source to correct a gain of the injection DTC. The delay equalizer may further include a calibration DTC configured to control a third error component (e.g., the INL error) of the plurality of error components. The calibration DTC may control the third error component by tuning a delay range relative to a delay range of an injection DTC. As such, the method 2600 may further include tuning or controlling a delay range relative to a delay range of an injection DTC via the calibration DTC. In some embodiments, outputs of an injection polarity error calibrator (e.g., the background error compensator) and the background delay equalizer are combined digitally before adjusting a delay of a calibration digital-to-time converter. In some embodiments, the outputs of the background error compensator and the background delay equalizer are not combined.

Implementations of the subject matter and the operations described in this specification can be implemented in digital electronic circuitry or computer software embodied on a tangible medium, firmware, or hardware, including the structures disclosed in this specification and their structural equivalents or combinations of one or more of them. Implementations of the subject matter described in this specification can be implemented as one or more computer programs, e.g., one or more components of computer program instructions encoded on a computer storage medium for execution by, or to control the operation of, data processing apparatus. The program instructions can be encoded on an artificially generated propagated signal, e.g., a machine-generated electrical, optical, or electromagnetic signal developed to transmit information to a suitable receiver apparatus for execution by a data processing apparatus. A computer storage medium can be, or be included in, a computer-readable storage device, a computer-readable storage substrate, a random or serial access memory array or device, or a combination of one or more. Moreover, while a computer storage medium is not a propagated signal, a computer storage medium can include a source or destination of computer program instructions encoded in an artificially generated propagated signal. The computer storage medium can also be included in one or more separate physical components or media (e.g., multiple CDs, disks, or other storage devices).

The features disclosed herein may be implemented on a smart television module (or connected television module, hybrid television module, etc.), which may include a processing module configured to integrate internet connectivity with more traditional television programming sources (e.g., received via cable, satellite, over-the-air, or other signals). The smart television module may be physically incorporated into a television set or may include a separate device such as a set-top box, Blu-ray or other digital media player, game console, hotel television system, and other companion devices. A smart television module may be configured to allow viewers to view videos, movies, photos, and other content on the web, on a local cable TV channel, on a satellite TV channel, or stored on a local hard drive. A set-top box (STB) or set-top unit (STU) may include an information appliance device that may contain a tuner and connect to a television set and an external source of signal, turning the signal into content that is then displayed on the television screen or other display device.

A data processing apparatus can implement the operations described in this specification on data stored on one or more computer-readable storage devices or received from other sources.

The terms “data processing apparatus”, “feature extraction system,” “data processing system”, “client device”, “computing platform”, “computing device”, or “device” encompasses all kinds of apparatus, devices, and machines for processing data, including by way of example a programmable processor, a computer, a system on a chip, or multiple ones, or combinations, of the preceding. The apparatus can include special purpose logic circuitry, e.g., an FPGA (field programmable gate array) or an ASIC (application-specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various computing models infrastructures, such as web services, distributed computing, and grid computing infrastructures.

A computer program (also known as a program, software, software application, script, or code) can be written in any programming language, including compiled or interpreted languages, and declarative or procedural languages. It can be deployed in any form, including as a stand-alone program or as a module, component, subroutine, object, or other units suitable for use in a computing environment. A computer program may, but need not, correspond to a file system file. A program can be stored in a portion of a file that holds other programs or data (e.g., one or more scripts stored in a markup language document), in a single file dedicated to the program in question, or in multiple coordinated files (e.g., files that store one or more modules, sub-programs, or portions of code). A computer program can be deployed to be executed on one computer or multiple computers located at one site or distributed across multiple sites and interconnected by a communication network.

The processes and logic flow described in this specification can be performed by one or more programmable processors executing one or more computer programs to perform actions by operating on input data and generating output. The processes and logic flows can also be performed by, and apparatuses can also be implemented as, special purpose logic circuitry, e.g., a field programmable gate array (FPGA) or an application-specific integrated circuit (ASIC).

Processors suitable for the execution of a computer program include, by way of example, both general and special purpose microprocessors and any one or more processors of any digital computer. Generally, a processor will receive instructions and data from a read-only memory (ROM) or a random-access memory (RAM) or media. The elements of a computer include a processor for performing actions following instructions and one or more memory devices for storing instructions and data. Generally, a computer will also include or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), for example. Devices suitable for storing computer program instructions and data include all forms of non-volatile memory, media, and memory devices, including way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented or incorporated into special-purpose logic circuitry.

To provide for interaction with a user, implementations of the subject matter described in this specification can be implemented on a computer having a display device, e.g., a cathode ray tube (CRT), plasma, or liquid crystal display (LCD) monitor, for displaying information to the user and a keyboard and a pointing device, e.g., a mouse or a trackball, by which the user can provide input to the computer. Other kinds of devices can be used to provide for interaction with a user as well; for example, feedback provided to the user can include any form of sensory feedback, e.g., visual feedback, auditory feedback, or tactile feedback; and input from the user can be received in any form, including acoustic, speech, or tactile input.

Implementations of the subject matter described in this specification can be implemented in a computing system that includes a back-end component, e.g., as a data server, or that includes a middleware component, e.g., an application server, or that includes a front-end component, e.g., a client computer having a graphical user interface or a Web browser through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

The computing system can include clients and servers. For example, the computing system can include one or more servers in data centers or server farms. A client and server are generally remote from each other and typically interact through a communication network. The relationship between client and server arises through computer programs running on the respective computers and having a client-server relationship. In some implementations, a server transmits data (e.g., an HTML page) to a client device (e.g., for displaying data to and receiving input from a user interacting with the client device). Data generated at the client device (e.g., a result of an interaction, computation, or any other event or computation) can be received from the client device at the server and vice-versa.

While this specification contains many specific implementation details, these should not be construed as limitations on the scope of any inventions or of what may be claimed but rather as descriptions of features specific to implementations of the systems and methods described herein. Certain features described in this specification in the context of separate implementations can also be combined in a single implementation. Conversely, various features described in the context of a single implementation can also be implemented separately or in any suitable subcombination. Moreover, although features may be described above as acting in certain combinations and even initially claimed as such, one or more features from a claimed combination can, in some cases, be excised from the combination, and the claimed combination may be directed to a subcombination or variation of a subcombination.

Similarly, while operations are depicted in the drawings in a particular order, this should not be understood as requiring that such operations be performed in the order shown or in sequential order or that all illustrated operations be performed to achieve desirable results. In some cases, the actions recited in the claims can be performed in a different order and still achieve desirable results. In addition, the processes depicted in the accompanying figures do not necessarily require the particular order shown, or sequential order, to achieve desirable results.

In certain circumstances, multitasking and parallel processing may be advantageous. Moreover, the separation of various system components in the above implementations should not be understood as requiring such separation in all implementations. It should be understood that the described program components and systems can generally be integrated with a single software product or packaged into multiple software products. For example, the computer system could be a single module or a logic device having one or more processing modules.

Having now described some illustrative implementations and implementations, it is apparent that the foregoing is illustrative and not limiting, having been presented by way of example. Although many of the examples presented herein involve specific combinations of method acts or system elements, those acts and those elements may be combined in other ways to accomplish the same objectives. Acts, elements and features discussed only in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation, and references to “an implementation,” “some implementations,” “an alternate implementation,” “various implementation,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The systems and methods described herein may be embodied in other specific forms without departing from the characteristics thereof. Although the examples provided may be useful for multiwavelet-based operator learning for differential equations, the systems and methods described herein may be applied to other environments. The foregoing implementations are illustrative rather than limiting of the described systems and methods. The scope of the systems and methods described herein may thus be indicated by the appended claims, rather than the foregoing description, and changes that come within the meaning and range of equivalency of the claims are embraced therein.

1. An electrical circuit for clock generation comprising:
a digital-to-time converter error scrambler configured to randomize error in a digital-to-time converter (DTC) and configured to suppress spurs of the electrical circuit;
a background error compensator configured to mitigate a timing mismatch between an injection of a reference signal into an oscillator at a first point and an injection of the reference signal into the oscillator at a second point; and
a background delay equalizer configured to calibrate errors of the electrical circuit.

2. The electrical circuit of claim 1, wherein randomization from the digital-to-time converter error scrambler and calibration from the background delay equalizer occur simultaneously.

3. The electrical circuit of claim 1, wherein randomization from the digital-to-time converter error scrambler and calibration from the background delay equalizer occur independently.

4. The electrical circuit of claim 1, wherein the errors calibrated by the background delay equalizer are any one of a digital-to-time converter offset, a digital-to-time converter gain, or an integral-nonlinearity (INL) error.

5. The electrical circuit of claim 3, wherein the errors exist at at least one point of a phase-locked loop.

6. The electrical circuit of claim 1, wherein a timing mismatch is associated with the digital-to-time converter error scrambler.

7. The electrical circuit of claim 1, wherein the electrical circuit is further configured to include one or more of a pulse window generator, an injection path, a digital-controlled oscillator, an injection mixer, an injection digital-to-time converter, or a calibration digital-to-time converter.

8. The electrical circuit of claim 1, wherein outputs of the background error compensator and the background delay equalizer are combined digitally before adjusting a delay of a calibration digital-to-time converter.

9. The electrical circuit of claim 7, wherein the pulse window generator controls the timing of a reference injection and an injection polarity.

10. An electrical circuit for clock generation comprising:
an oscillator;
a digital-to-time converter (DTC) error scrambler configured to randomize error in a DTC and configured to suppress spurs of the electrical circuit, wherein the DTC error scrambler comprises control code to control a delay of one or more injection DTCs;
a background error compensator configured to mitigate a timing mismatch between an injection of a reference signal into the oscillator at a first point and an injection of the reference signal into the oscillator at a second point; and
a background delay equalizer configured to calibrate errors of the electrical circuit, wherein the errors comprise a plurality of error components.

11. The electrical circuit of claim 10, wherein the background delay equalizer comprises:
digital domain corrector configured to tune the oscillator to align with a phase of at least one of the injection DTCs to control a first error component of the plurality of error components;
a current source configured to control a second error component of the plurality of error components; and
a calibration DTC configured to control a third error component of the plurality of error components.

12. The electrical circuit of claim 11, wherein the first error component is a digital-to-time converter offset error, the second error component is a digital-to-time converter gain error, and the third error component is a digital-to-time converter integral-nonlinearity (INL) error.

13. The electrical circuit of claim 12, wherein the calibration DTC controls the third error component by reducing a delay range relative to a delay range of an injection DTC.

14. The electrical circuit of claim 11, wherein mitigating the timing mismatch between the injection of the reference signal into the oscillator at the first point and the injection of the reference signal into the oscillator at the second point comprises:
extracting, by the background error compensator, using a filter, the timing mismatch between the injection of the reference signal at the first point and the injection of the reference signal at the second point; and
tuning control code of the calibration DTC to calibrate a time delay of one or both of the injection of the reference signal at the first point and the injection of the reference signal at the second point.

15. The electrical circuit of claim 10, the electrical circuit further comprising a reference signal configured to periodically refresh a signal of the oscillator to suppress noise in the oscillator, wherein the reference signal is a low noise signal.

16. The electrical circuit of claim 10, wherein a total delay of the one or more injection DTCs is determined based on a product of a gain of the injection DTC and the control code of the injection DTC.

17. The electrical circuit of claim 10, wherein the background delay equalizer comprises a least mean square filter.

18. A method comprising:
controlling, using a digital-to-time converter (DTC) error scrambler, a delay of one or more injection DTCs of an electrical circuit;
mitigating, using a background error compensator, a timing mismatch between an injection of a reference signal into an oscillator at a first point and an injection of the reference signal into the oscillator at a second point; and
calibrating, using a delay equalizer, error of the electrical circuit, the error comprising a plurality of error components.

19. The method of claim 18, wherein calibrating the plurality of error components comprises:
tuning a signal of the oscillator to align with a phase of at least one of the one or more injection DTCs to control a first error component of the plurality of error components;
controlling a current source to correct a gain of the injection DTC; and
tuning a delay range relative to a delay range of an injection DTC via a calibration DTC.

20. The method of claim 18, wherein mitigating the timing mismatch comprises:
extracting, by the background error compensator, using a filter, the timing mismatch between the injection of the reference signal at the first point and the injection of the reference signal at the second point; and
tuning control code of the calibration DTC to calibrate a time delay of one or both of the injection of the reference signal at the first point and the injection of the reference signal at the second point.
